(19) United States
(12) Patent Application Publication
(10) Pub. No.: US 2010/0206350 A1
(43) Pub. Date: Aug. 19, 2010

(54) PHOTOVOLTAIC CELL ARRAYS

(76) Inventors: Alan John Montello, West Newbury, MA (US); Christopher Graham Anderson, Gwent (GB); Kevin Daniel Tabor, Cardiff (GB); Marcus Yalland, Gwent (GB); Martin Bellamy, Cardiff (GB); Anthony David Jones, Caerphilly (GB)

Correspondence Address: K&L Gates LLP, STATE STREET FINANCIAL CENTER, One Lincoln Street, BOSTON, MA, 02111-2950, US

(21) Appl. No.: 12/533,810

(22) Filed: Jul. 31, 2009

Related U.S. Application Data
(63) Continuation-in-part of application No. PCT/GB2008/000353, filed on Feb. 4, 2008.
Application No. PCT/GB2008/000353 is a continuation-in-part of application No. PCT/GB2008/000349, filed on Feb. 4, 2008.
Application No. PCT/GB2008/000349 is a continuation-in-part of application No. PCT/GB2008/000380, filed on Feb. 4, 2008.
Application No. PCT/GB2008/000380 is a continuation-in-part of application No. PCT/GB2008/000379, filed on Feb. 4, 2008.
Application No. PCT/GB2008/000379 is a continuation-in-part of application No. PCT/GB2008/000375, filed on Feb. 4, 2008.
Application No. PCT/GB2008/000375 is a continuation-in-part of application No. PCT/GB2008/000374, filed on Feb. 4, 2008.
Application No. PCT/GB2008/000374 is a continuation-in-part of application No. PCT/GB2008/000372, filed on Feb. 4, 2008.
Application No. PCT/GB2008/000372 is a continuation-in-part of application No. PCT/GB2008/000371, filed on Feb. 4, 2008.
Application No. PCT/GB2008/000371 is a continuation-in-part of application No. PCT/GB2008/000370, filed on Feb. 4, 2008.
Application No. PCT/GB2008/000370 is a continuation-in-part of application No. PCT/GB2008/000369, filed on Feb. 4, 2008.
Application No. PCT/GB2008/000369 is a continuation-in-part of application No. PCT/GB2008/000368, filed on Feb. 4, 2008.
Application No. PCT/GB2008/000368 is a continuation-in-part of application No. PCT/GB2008/000365, filed on Feb. 4, 2008.
Application No. PCT/GB2008/000365 is a continuation-in-part of application No. PCT/GB2008/000364, filed on Feb. 4, 2008.
Application No. PCT/GB2008/000364 is a continuation-in-part of application No. PCT/GB2008/000363, filed on Feb. 4, 2008.
Application No. PCT/GB2008/000363 is a continuation-in-part of application No. PCT/GB2008/000362, filed on Feb. 4, 2008.
Application No. PCT/GB2008/000362 is a continuation-in-part of application No. PCT/GB2008/000361, filed on Feb. 4, 2008.
Application No. PCT/GB2008/000361 is a continuation-in-part of application No. PCT/GB2008/000360, filed on Feb. 4, 2008.
Application No. PCT/GB2008/000360 is a continuation-in-part of application No. PCT/GB2008/000359, filed on Feb. 4, 2008.
Application No. PCT/GB2008/000359 is a continuation-in-part of application No. PCT/GB2008/000358, filed on Feb. 4, 2008.
Application No. PCT/GB2008/000358 is a continuation-in-part of application No. PCT/GB2008/000357, filed on Feb. 4, 2008.
Application No. PCT/GB2008/000357 is a continuation-in-part of application No. PCT/GB2008/000356, filed on Feb. 4, 2008.
Application No. PCT/GB2008/000356 is a continuation-in-part of application No. PCT/GB2008/000355, filed on Feb. 4, 2008.
Application No. PCT/GB2008/000355 is a continuation-in-part of application No. PCT/GB2008/000354, filed on Feb. 4, 2008.
Application No. PCT/GB2008/000354 is a continuation-in-part of application No. PCT/GB2008/000351, filed on Feb. 4, 2008.
Application No. PCT/GB2008/000351 is a continuation-in-part of application No. PCT/GB2008/000350, filed on Feb. 4, 2008.

(30) Foreign Application Priority Data
Feb. 2, 2007 (GB) 0702042.3
Feb. 2, 2007 (GB) 0702043.1
Feb. 2, 2007 (GB) 0702044.9
Feb. 2, 2007 (GB) 0702045.6
Feb. 2, 2007 (GB) 0702046.4
Feb. 2, 2007 (GB) 0702047.2
Feb. 2, 2007 (GB) 0702048.0
Feb. 2, 2007 (GB) 0702049.8
Aug. 16, 2007 (GB) 0716039.3
Aug. 16, 2007 (GB) 0716040.1
Aug. 16, 2007 (GB) 0716041.9
Aug. 16, 2007 (GB) 0716042.7
Aug. 16, 2007 (GB) 0716043.5
Aug. 16, 2007 (GB) 0716044.3

(51) Int. Cl. H01L 31/042; B29C 65/00; B05D 3/06; B23K 31/02; B05C 9/00; B05C 11/00

(52) U.S. Cl. 136/244; 156/60; 427/554; 228/170; 118/58; 118/642

(57) ABSTRACT

A method of manufacturing a photovoltaic cell array of the type comprising a primary electrode array and a counter-electrode array together defining a series-connected sequence of cells, each containing electrolyte which is insulated from direct electrical contact with the electrolyte of neighbouring cells, the method comprising: (a) depositing electrolyte into the cells; and (b) sensing the level of electrolyte deposited.

### REFERENCE TO RELATED APPLICATIONS

This application is a continuation of International Patent Application Nos. PCT/GB2008/000353, PCT/GB2008/000349, PCT/GB2008/000380, PCT/GB2008/000379, PCT/GB2008/000375, PCT/GB2008/000374, PCT/GB2008/000372, PCT/GB2008/000371, PCT/GB2008/000370, PCT/GB2008/000369, PCT/GB2008/000368, PCT/GB2008/000365, PCT/GB2008/000364, PCT/GB2008/000363, PCT/GB2008/000362, PCT/GB2008/000361, PCT/GB2008/000360, PCT/GB2008/000359, PCT/GB2008/000358, PCT/GB2008/000357, PCT/GB2008/000356, PCT/GB2008/000355, PCT/GB2008/000354, PCT/GB2008/000351 and PCT/GB2008/000350, all filed Feb. 4, 2008. Each of the above-identified International Patent Applications claims priority to and the benefit of United Kingdom Patent Application Nos. 0702049.8, 0702042.3, 0702043.1, 0702044.9, 0702045.6, 0702046.4, 0702047.2, 0702048.0, all filed Feb. 2, 2007. Each of the above-identified International Patent Applications also claims priority to and the benefit of United Kingdom Patent Application Nos. 0716040.1, 0716041.9, 0716042.7, 0716043.5, 0716039.3, 0716044.3, all filed Aug. 16, 2007. The entire disclosures of each of the above-identified applications are hereby incorporated by reference herein.

### TECHNICAL FIELD

The present invention relates to photovoltaic cell arrays and in particular to methods for use in the manufacture thereof. In part, the invention relates to improvements regarding dye sensitized solar cells (DSSC) and methods of making the same.

### BACKGROUND

In one type of photovoltaic cell array, a primary electrode array and a counter-electrode array together define a series-connected sequence of cells, each containing electrolyte which is insulated from direct electrical contact with the electrolyte of neighbouring cells. During manufacture of such an array, it is necessary to deposit the electrolyte material into each of the cells. To achieve optimum performance of the array, it is important that the electrolyte layer has a relatively uniform, pre-defined thickness.

Typically, the electrolyte material is in a liquid form, and may be relatively viscous. Accordingly, it would be desirable to provide a method for manufacturing a photovoltaic cell array in which the electrolyte can be easily deposited within the cells of the array while ensuring that the required thickness of the electrolyte layer has been achieved.

In one process for manufacturing primary electrodes for photovoltaic cell arrays, a raised profile is formed in the surface of an electrical conductor, such as a metal web, for establishing electrical connections with a counter-electrode. A coating, such as an oxide coating, is applied or otherwise formed on the surface of the electrical conductor to provide a component of the photovoltaic cell array, such as an insulating layer or dye carrier. The electrical conductor is then heated so as to dry the coating.

The coating may be applied over the raised profile of the electrical conductor, and must subsequently be removed so as to allow the formation of a good electrical connection with the counter-electrode.

Indeed, even if the coating is applied only to a selected region of the electrical conductor and not on the raised profile, the heating process tends to result in the formation of an electrically-insulating oxide layer or similar coating over the whole surface of the electrical conductor, including the raised profile. Again, the coating present on the raised profile must be removed to allow the formation of a sound electrical connection with the counter-electrode.

Often, the coating cannot be mechanically removed, for example by polishing or grinding, without causing damage to the underlying electrical conductor.

### SUMMARY OF THE INVENTION

In accordance with the present invention there is provided a method of manufacturing a photovoltaic cell array of the type comprising a primary electrode array and a counter-electrode array together defining a series-connected sequence of cells, each containing electrolyte which is insulated from direct electrical contact with the electrolyte of neighbouring cells, the method comprising: (a) depositing electrolyte into the cells; and (b) sensing the level of electrolyte deposited.

By sensing the level of electrolyte deposited in this way, the present invention ensures that the desired thickness of electrolyte in the cells has been achieved, so that the performance of the resulting array is optimised in that regard.

Preferably, the level of electrolyte in each cell is sensed independently. The level of electrolyte may conveniently be sensed using one or more optical colorimetric sensors. Alternatively, or in addition, the level of electrolyte may be sensed using one or more optical reflective sensors.

The method may further comprise controlling the rate of deposition of the electrolyte in dependence on the sensed level of electrolyte. For example, if the sensed level of electrolyte is too low at a given time, the rate of deposition of the electrolyte can be increased to correct the level of electrolyte. Likewise, if the sensed level of electrolyte is too high, the rate of deposition can be reduced accordingly.

Preferably, the electrolyte is deposited using a separate respective dispenser for each cell. The electrolyte may be deposited using one or more solenoid-controlled dosing valves.

Each cell in the said one electrode array may be defined by a respective pair of insulating tracks. For example, each insulating track may comprise a hot-melt adhesive which additionally serves to adhere the primary electrode array and the counter-electrode array together. Each insulating track may additionally comprise an insulating fiber. Alternatively, or in addition, each insulating track may further comprise a plurality of glass spheres which serve to define the spacing between the primary electrode array and the counter-electrode array.

It is also an object of the present invention to provide a method of preparing a primary electrode which allows removal of a coating or surface layer from a selected region of the surface of an electrical conductor whilst preventing damage to the electrical conductor.

In accordance with the present invention there is provided a method of preparing a primary electrode array for use in a photovoltaic array, the method comprising the steps of: (a) forming a raised profile in a first region of the surface of an electrical conductor for establishing one or more electrical connections with a counter-electrode array; (b) applying a coating to the surface of the electrical conductor to form a component of the photovoltaic array; (c) heating the electrical conductor so as to dry the coating; and (d) applying laser radiation to the first region of the surface of the electrical conductor, thereby to remove any coating formed thereon in step (b) and to remove any reaction product formed thereon in step (c).

The use of laser radiation allows the coating or reaction product to be removed accurately and precisely from the first region, without damaging the coating elsewhere. Furthermore, little or no debris remains on the surface on the electrical conductor after application of the laser radiation.

The first region may, for example, comprise one or more tracks along the surface of the electrical conductor. The electrical conductor may be in the form of a web.

Step (b) of the method may include applying a coating to only a second region of the surface of the electrical conductor which is different from the first region. In this embodiment and when the first region comprises one or more tracks along the surface of the electrical conductor, the second region may optionally comprise the one or more tracks defined by the regions between the one or more tracks of the first region.

Step (b) may instead comprise applying a coating to substantially the entire surface of the electrical conductor. This option is made possible because the use of laser radiation in present invention allows accurate and precise removal of the coating from the first region. In this expression of the method, complex apparatus such as extrusion apparatus for applying the coating to only a second region of the surface of the electrical conductor need not be provided.

In one expression of the method, step (d) comprises transporting the electrical conductor in a transport direction relative to a source of laser radiation and scanning the laser radiation across the first region in a direction transverse to the transport direction. Alternatively, step (d) may comprise transporting the electrical conductor in a transport direction relative to a source of laser radiation and applying the laser radiation simultaneously to those parts of the first region which intersect a linear region extending transverse to the transport direction.

The electrical conductor may comprise titanium. The coating may comprise titanium dioxide.

The method is particularly suitable for use in the manufacture of electrodes for flexible photovoltaic arrays, and accordingly the present invention extends to a method of manufacturing a primary electrode for a flexible photovoltaic array comprising a method of preparing a primary electrode array as previously described, and a method of manufacturing a flexible photovoltaic array comprising a method of preparing a primary electrode array as previously described.

In addition, the invention provides a method of forming a dye sensitized solar cell. The method includes the steps of (a) applying an electrolyte mixture to a first electrode web, wherein the electrolyte mixture is applied sequentially at a first location using a first applicator and at a second location using a second applicator; (c) heating the electrolyte mixture at the first location to increase diffusion of the electrolyte mixture relative to the electrode web; and (d) joining the first electrode web with a second electrode web to form a plurality of dye sensitized solar cells.

The method of forming a dye sensitized solar cell can include one or more of the following embodiments. In some embodiments, the step of joining the first electrode web with a second electrode web is performed using a first textured roller pair, a second textured roller pair and a third flat roller pair, the pressure exerted on each electrode web by the second roller pair is greater than that exerted by the first roller pair. In some embodiments, the electrolyte mixture comprises a first component and a second component, the first component applied using the first applicator and the second component applied using the second applicator. In some embodiments, the first component comprises a greater amount of solvent relative to the second component. In some embodiments, the first component comprises a greater amount of electrolyte relative to the second component. In some embodiments, the first component comprises about 67% solvent and about 33% electrolyte. In some embodiments, the second component comprises about 33% solvent and about 67% electrolyte.

The invention also provides a method of preparing a primary electrode array for use in a photovoltaic array. The method includes the steps of: (a) forming a raised profile in a first region of the surface of an electrical conductor for establishing one or more electrical connections with a counter-electrode array; (b) applying a coating to the surface of the electrical conductor to form a component of the photovoltaic array; (c) heating the electrical conductor so as to dry the coating; and (d) applying laser radiation to the first region of the surface of the electrical conductor, thereby to remove any coating formed thereon in step (b) and to remove any reaction product formed thereon in step (c).

The method of preparing a primary electrode array for use in a photovoltaic array can include one or more of the following embodiments. In some embodiments, the first region comprises one or more tracks along the surface of the electrical conductor. In some embodiments, step (b) includes applying a coating to only a second region of the surface of the electrical conductor which is different from the first region. In some embodiments, the second region comprises the one or more tracks defined by the regions between the one or more tracks of the first region. In some embodiments, step (b) comprises applying a coating to substantially the entire surface of the electrical conductor. In some embodiments, step (d) comprises transporting the electrical conductor in a transport direction relative to a source of laser radiation and scanning the laser radiation across the first region in a direction transverse to the transport direction. In some embodiments, step (d) comprises transporting the electrical conductor in a transport direction relative to a source of laser radiation and applying the laser radiation simultaneously to those parts of the first region which intersect a linear region extending transverse to the transport direction. In some embodiments, the electrical conductor is in the form of a web. In some embodiments, the electrical conductor comprises titanium or alternative conductors. In some embodiments, the coating comprises titanium dioxide or other materials.

The invention also provides a method of manufacturing a primary electrode for a flexible photovoltaic array comprising a method of preparing a primary electrode array as claimed in any one of the foregoing embodiments.

The invention also provides a method of manufacturing a flexible photovoltaic array comprising a method of preparing a primary electrode array as claimed in any of the foregoing embodiments.

The invention also provides a method of manufacturing a photovoltaic cell array of the type comprising a primary electrode array and a counter-electrode array together defining a series-connected sequence of cells, each containing electrolyte which is insulated from direct electrical contact with the electrolyte of neighbouring cells. The method includes the steps of (a) depositing electrolyte into the cells; and (b) sensing the level of electrolyte deposited.

The method of manufacturing a photovoltaic cell array can include one or more of the following embodiments. In some embodiments, the level of electrolyte in each cell is sensed independently. In some embodiments, the level of electrolyte is sensed using one or more optical colorimetric sensors. In some embodiments, the level of electrolyte is sensed using one or more optical reflective sensors. In some embodiments, the method includes the additional step of controlling the rate of deposition of the electrolyte using a feedback loop that uses the sensed level of electrolyte as an input. In some embodiments, the electrolyte is deposited using a separate respective dispenser for each cell. In some embodiments, the electrolyte is deposited using one or more solenoid-controlled dosing valves. In some embodiments, each cell in the said one electrode array is defined by a respective pair of insulating tracks. In some embodiments, each insulating track comprises a hot-melt adhesive which additional serves to adhere the primary electrode array and the counter-electrode array together. In some embodiments, each insulating track additionally comprises an insulating fiber. In some embodiments, each insulating track additionally comprises a plurality of glass spheres which serve to define the spacing between the primary electrode array and the counter-electrode array.

### BRIEF DESCRIPTION OF DRAWINGS

The figures are not necessarily to scale, emphasis instead generally being placed upon illustrating the principles of the invention. The figures are to be considered illustrative in all aspects and are not intended to limit the invention, the scope of which is defined solely by the claims.

Preferred embodiments of the present invention will now be described with reference to the accompanying drawings wherein:

FIG. 1 illustrates the overall process for manufacturing a photovoltaic cell, in accordance with an illustrative embodiment of the invention;

FIG. 2 illustrates the process for manufacturing a primary electrode array of the photovoltaic cell array, in accordance with an illustrative embodiment of the invention;

FIG. 3 illustrates the processes involved in embossing a pattern on the titanium web of the primary electrode array, in accordance with an illustrative embodiment of the invention;

FIG. 4 illustrates the path of the titanium web of the primary electrode through the embossing rollers, in accordance with an illustrative embodiment of the invention;

FIG. 5 illustrates the respective male (raised) and female (recessed) profile of the embossing rollers which produce the small spherical projections on the titanium web of the primary electrode array, when viewed along the axes of the rollers, in accordance with an illustrative embodiment of the invention;

FIG. 6 illustrates the process for cleaning the titanium web of the primary electrode array, in accordance with an illustrative embodiment of the invention;

FIG. 7 is a cross-sectional view of apparatus for cleaning the embossed titanium web, in accordance with an illustrative embodiment of the invention;

FIG. 8 illustrates the process for coating the titanium web with titanium dioxide, in accordance with an illustrative embodiment of the invention;

FIG. 9 illustrates the cleaning of a coated titanium web by a laser, in accordance with an illustrative embodiment of the invention;

FIG. 10 illustrates the process for coating the titanium dioxide layer on the titanium web with a ruthenium-based dye, in accordance with an illustrative embodiment of the invention;

FIG. 11 illustrates an arrangement for applying a layer of dye to the coated titanium web, in accordance with an illustrative embodiment of the invention;

FIG. 12 illustrates the final stages in the fabrication of the primary electrode array in accordance with an embodiment of the present invention, in accordance with an illustrative embodiment of the invention;

FIGS. 13(a) and 13(b) illustrate first and second alternative types of dynamic tensioning device for use in the arrangement of FIG. 12, in accordance with an illustrative embodiment of the invention;

FIG. 14 illustrates the final stages in the fabrication of the counter-electrode array in accordance with an embodiment of the present invention, in accordance with an illustrative embodiment of the invention;

FIG. 15 illustrates how the primary electrode array and the counter-electrode array are joined together in accordance with an embodiment of the present invention, in accordance with an illustrative embodiment of the invention;

FIGS. 16(a) to 16(c) are cross-sectional views of the photovoltaic cell array in accordance with a preferred embodiment of the present invention, at different stages in the fabrication, in accordance with an illustrative embodiment of the invention;

FIG. 17 illustrates how the primary electrode array and the counter-electrode array are joined together in accordance with a further embodiment of the present invention, in accordance with an illustrative embodiment of the invention;

FIG. 18 is a cross-sectional view of the final lamination process, in accordance with an illustrative embodiment of the invention;

FIG. 19(a) illustrates how an external electrical connection is made to the photovoltaic cell array in accordance with a preferred embodiment of the present invention, in accordance with an illustrative embodiment of the invention;

FIG. 19(b) is a cross-sectional view on X-X of a portion of the electrical connection shown in FIG. 19(a), in accordance with an illustrative embodiment of the invention;

FIG. 20(a) is an exploded cross-sectional view of a portion of two adjacent cells of the primary electrode and counter-electrode arrays before assembly, in accordance with an illustrative embodiment of the invention;

FIG. 20(b) is a cross-sectional view of a portion of two adjacent cells of the laminated assembled primary electrode and counter-electrode arrays, in accordance with an illustrative embodiment of the invention;

FIG. 21 is a cross-sectional view showing the dimensions of the components of an assembled photovoltaic cell array in accordance with a preferred embodiment of the present invention, in accordance with an illustrative embodiment of the invention;

FIG. 22 shows the overall appearance of the assembled photovoltaic cell array, in accordance with an illustrative embodiment of the invention;

FIGS. 23A and 23B show different views of a slot dye applicator suitable for depositing material on a substrate in a substantially regular pattern; and

FIG. 23C shows a plurality of rectangular or striped regions deposited on a substrate using the embodiment of FIGS. 23A and 23B.

### DETAILED DESCRIPTION

The use of sections in the application is not meant to limit the invention; each section can apply to any aspect, embodiment, or feature of the invention.

It should be understood that the order of the steps of the methods of the invention is immaterial so long as the invention remains operable. Moreover, two or more steps may be conducted simultaneously or in a different order than recited herein unless otherwise specified.

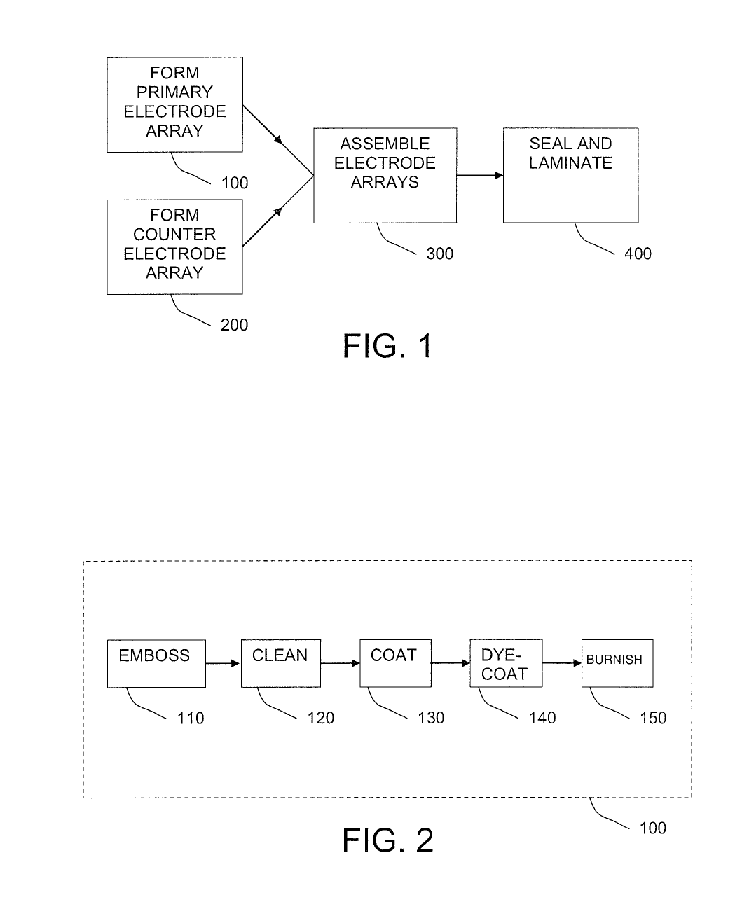

Referring to FIG. 1, a process for manufacturing an array of photovoltaic cells includes: a process 100 for forming an array of primary electrodes; a process 200 for forming a corresponding array of counter-electrodes; a process 300 for assembling the two electrode arrays with electrolyte there between; and a process 400 for sealing the edges of the assembled electrode arrays and laminating the sealed assembly.

In one embodiment, the resulting sealed assembly comprises 11 functioning pairs of electrodes and one pair of dummy electrodes at the side edge of the array which is used for establishing external electrical contacts.

FIG. 2 illustrates in greater detail the process 100 for forming the primary electrode array. There are several separate stages to this process: embossing 110 the conductive web; cleaning 120; applying, drying, and sintering titanium dioxide colloid as part of a coating step 130; and applying 140 a ruthenium-based dye which acts as the light-absorbing material in the array of photovoltaic cells. Next, a burnishing step 150 is performed to remove unwanted TiOx residue and other unwanted materials. The burnishing can be performed using a mechanical device in one embodiment. In one embodiment, the burnishing step 105 removes any residual insulating oxide or remaining dye, such as waxy dye residue. The burnishing step and resultant removal of these unwanted waxy and insulating materials improves electrical interconnection (removal of insulation) and adhesion (removal of waxy materials that reduce adhesion) when fabricating DSSCs.

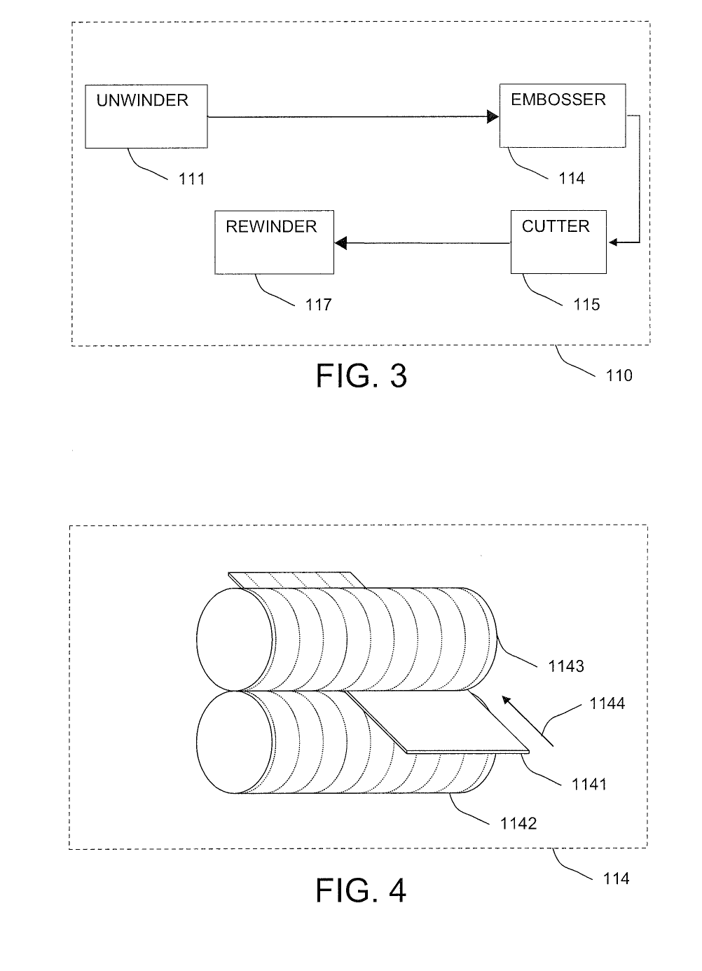

The apparatus used in the embossing process is illustrated in greater detail in FIG. 3. In this process a roll of titanium web having a thickness of about 0.01 mm to about 0.1 mm, with about 0.05 mm being preferred in the current embodiment, is unwound from an unwinding stage 111. A cutter 115 can optionally be used in some embodiments to pre-slit portions of the substrate. The titanium web is then supplied to an embossing stage 114 at which the web is embossed with a pattern of raised features of varying designs with the preferred design being about 0.085 mm high elongated shapes described in greater detail below, and the embossed web is supplied to a rewinding stage 117 which rewinds the embossed titanium web on to a core on a rewinding unit.

The embossing stage 114 is shown in greater detail in FIG. 4. The titanium web 1141 is fed into a nip defined by first and second embossing rollers 1142, 1143 along the direction shown by arrow 1144. The size of the nip is chosen so as to engage the titanium web which in one embodiment, has a thickness of about 0.05 mm, and is therefore selected to be a value preferably within the range of about 0.01 mm and about 0.10 mm; for other embodiments the size of the nip would depend on the thickness of the web. The embossing rollers 1142, 1143 are formed with a multiplicity of lines of embossing patterns for forming corresponding parallel lines of raised on the titanium web 1141, although only a few lines are illustrated in FIG. 4 for the sake of clarity.

As can be seen in FIG. 4, the titanium web 1141 occupies only one half of the width of the embossing rollers 1142, 1143. The titanium web 1141 therefore engages with one half of the lines of embossing patterns. In some embodiments this advantageous feature enables the embossing rollers 1142, 1143 to continue to be used in the event of a defect occurring in the embossing pattern on one side of one or both of the rollers 1142, 1143. A means of aligning the titanium web (not shown) is therefore provided so that, in the event of such a defect, the web can simply be realigned with the other side of the embossing pattern, so that the embossing process can continue without a substantial interruption in the process.

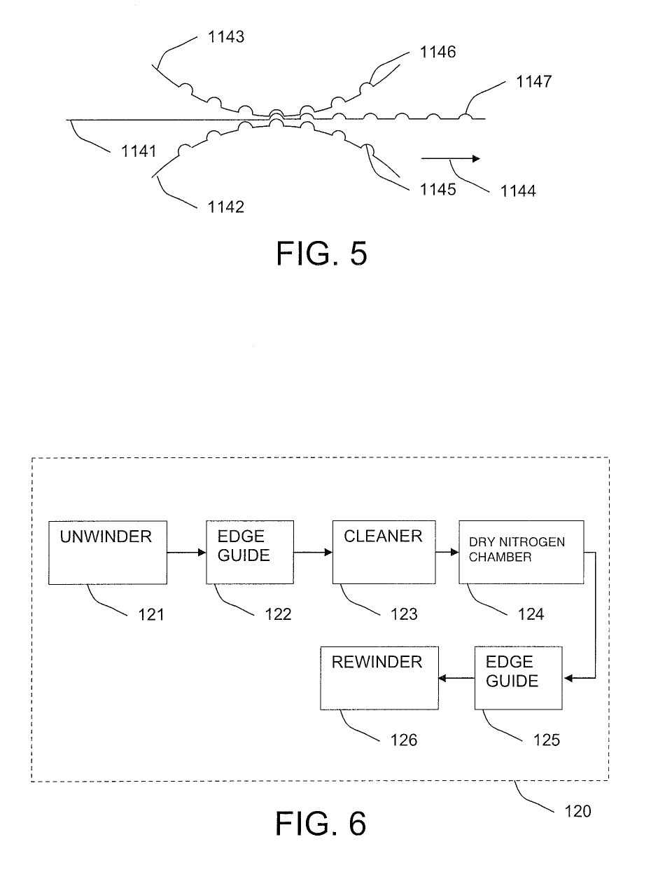

The surfaces of the embossing rollers 1142, 1143 are shown in greater detail in FIG. 5. The surface of the first embossing roller 1142 is formed with a raised (male) embossing pattern in the form of an array of near-spherical oblong, elongate or varying projections, depending on the embodiment, 1145 which are aligned with a recessed (female) embossing pattern in the form of a corresponding array of near-spherical recesses 1146. In one embodiment, an elongate embossing pattern, such as a diamond shaped pattern can be used. When an elongate pattern is used, this pattern operates as a hinge which facilitates the rolling of the final sheet of interconnected DSSCs. The scale of the embossing patterns shown in FIG. 5 is exaggerated relative to that of the embossing rollers 1142, 1143, for the sake of clarity. By passing the titanium web 1141 between the first and second embossing rollers 1142, 1143, an array of dimples 1147 is formed on the titanium web 1141. The dimples 1147 are formed in a rectangular array in which the spacing between adjacent dimples along the direction of travel of the titanium web 1141 is substantially less than that along the width of the titanium web. The dimples 1147 are thus formed in a number of lines, in which the dimples may be regularly spaced and may be separated at varying intervals, and the lines are separated by fixed but variable distance. The dimples 1147 serve as a means of establishing an electrical connection between the two electrodes of each photovoltaic cell within the assembled array.

In a manufacturing process the embossing process is started by using inexpensive materials as leader and trailer in order to minimize the loss expensive materials, for example the titanium web in the current embodiment. It will be appreciated that there are commercial automatic splicers available to perform this operation continuously.

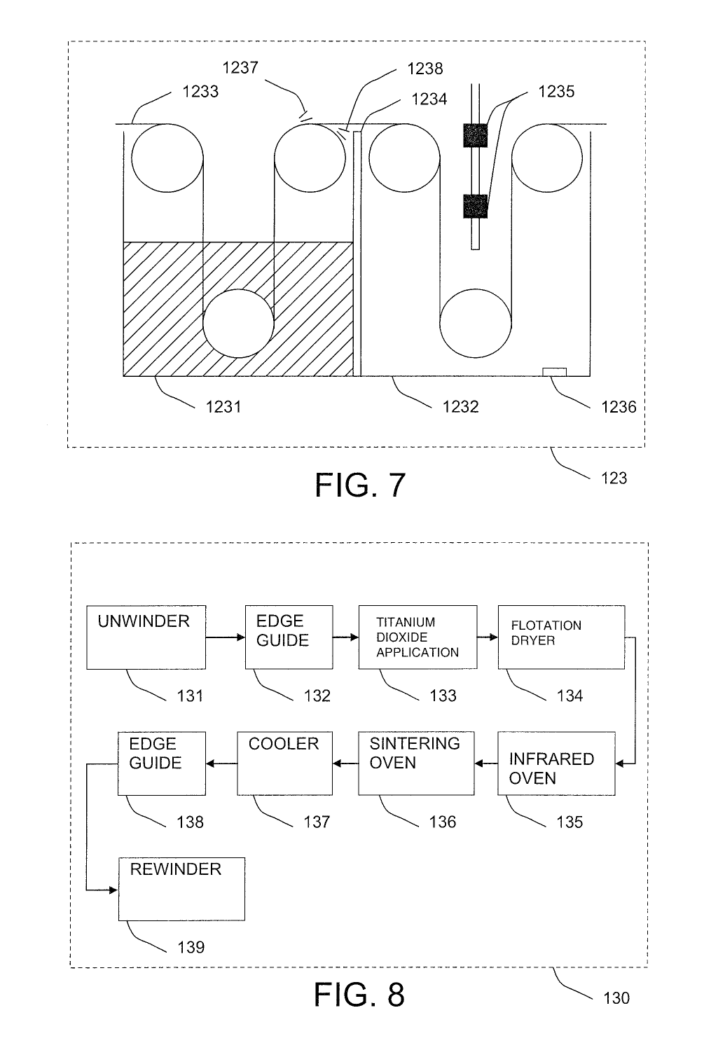

After the titanium web has been embossed, the embossed web is passed to a cleaning stage 120, shown in greater detail in FIG. 6. The cleaning stage serves to remove oil residues and other contaminants and comprises, in sequence, an unwinder 121, an edge guide 122, a cleaning unit 123, a dry nitrogen chamber, an edge guide 125 and a rewinder 126. In operation, the embossed titanium web is unwound and passed via the edge guide 122 into the cleaning unit 123. Referring to FIG. 7, the cleaning unit 123 comprises an ultrasonic bath 1231 of liquid detergent such as that marketed under the brand name LiquiNox® and multiple rinsing chambers 1232 including deionised water and ethanol rinse. The bath 1231 and the rinsing chamber 1232 are both heated to 85° C. The embossed titanium web 1233 is guided through the detergent in the bath 1231 and over a separating wall 1234 into the rinsing chamber 1232. De-ionised water is then sprayed on to the web 1233 from spray nozzles 1235 and is collected at the base of the rinsing chamber 1232 via a drainage outlet 1236. In some embodiments of the invention, the cleaning stage 120 may be omitted.

To prevent cross-contamination, first and second rows of air knives 1237, 1238 are positioned respectively above and below the path of the web 1233 a short distance upstream of the wall 1234, and these serve to force any detergent residue on the web 1233 back into the bath 1231.

The rinsed titanium web 1233 is then immersed in a bath of ethanol (not shown) and fed to a chamber purged with dry nitrogen at ambient temperature. The dried titanium web is then conveyed via an edge guide 125 to a rewinding station 126.

Referring back to FIG. 2, the embossed and cleaned titanium web is then supplied to a coating station 130 for depositing a layer of titanium dioxide (TiO₂) on the titanium web, and this is shown in greater detail in FIG. 8. An unwinder 131 supplies the web via an edge guide 132 to the TiO₂ application station (or applicator) 133, described in greater detail below. At the titanium dioxide colloid application station 133, a water-based colloid containing TiO₂ is dispensed, metered and applied on to the web from a pressurised container and is deposited in the form of stripes which extend between adjacent rows of embossed dimples.

In a preferred embodiment, the colloid contains: (a) a binder such as hydroxypropylcellulose (HPC) as a rheology modifying agent, which has the advantage of decomposing without leaving an undesirable residue on the web; a surfactant, for example as marketed under the reference TX-100 (4-octylphenol polyethoxylate) offered by the Dow Chemical Company which reduces the surface tension of the colloid thereby allowing the TiO₂ to uniformly wet the conductive substrate; and may contain a biocide for killing the moulds and fungi which are often found in the presence of HPC. The thickness of the TiO₂ paste deposited on the web is dependent on the shape of the geometry of the coating head, particularly the height of the coating slot, the speed at which the web is moved past the extrusion head, the rheology of the colloid and the metering rate of the fluid. It is important to have uniformity of the colloid across the titanium which uniformity also depends on the uniformity of the temperature across the applicator because this has a significant effect on rheology.

The TiO₂ colloid is then dried in three stages 134, 135, 136. The first stage 134 comprises a flotation dryer with backside heating of the non-coated side of the working material or substrate. In one embodiment, the colloid is heated to approximately 60° C. It is advantageous to dry the TiO₂ colloid from the non-coated side to prevent cracking and other damage to the colloid. Thus, by heating the colloid from the other side of the web or substrate adverse blistering on the surface of the coating is prevented. Optionally, the first stage 134 instead comprises a floatation drier followed by an infrared dryer both drying from the bottom to the top. The second stage 135 comprises an infrared dryer oven or flotation dryer (or a combination of both) in which the web is suspended and dried by infrared radiation and warm air. In one embodiment, the warm air is at a temperature of around 180° C. As is preferable the case with the first stage 134, the heat is applied to the non-coated side of the substrate containing the colloid to heat from the bottom up through the colloid. The third stage 136 comprises an infrared sintering oven which causes the TiO₂ from the colloid or paste (depending on which is used) to bind on the surface of the underlying titanium web, burn off or otherwise vaporize the organic solvents present in the material and fuse the TiO₂ nanoparticles. By fusing the nanoparticles, capillaries are formed which are suitable for receiving the dyes necessary to make operative DSSCs. The coated web then enters a cooling stage 137 or cools without further handling before being fed via an edge guide 138 to a rewinder 139.

It has been found that the process of sintering gives rise to an undesirable layer of oxide over the regions of the titanium foil between the tracks of titanium dioxide coating. Since these regions include the embossed dimples, it is possible to remove the oxide layer by conventional abrasion techniques without the risk of damaging the dimples. However, it has been found that the undesirable oxide coating can effectively be removed by scanning a high-power laser beam across the surface of the regions where the oxide is to be removed. The precision which is afforded by such laser cleaning permits removal of the undesirable oxide layer without affecting the tracks of titanium dioxide coating. Furthermore, this method is clean since it leaves no undesirable residue on the surface of the titanium foil which would otherwise require removal. The laser can additionally be used to apply a mark to the rear surface of the titanium foil for quality control purposes.

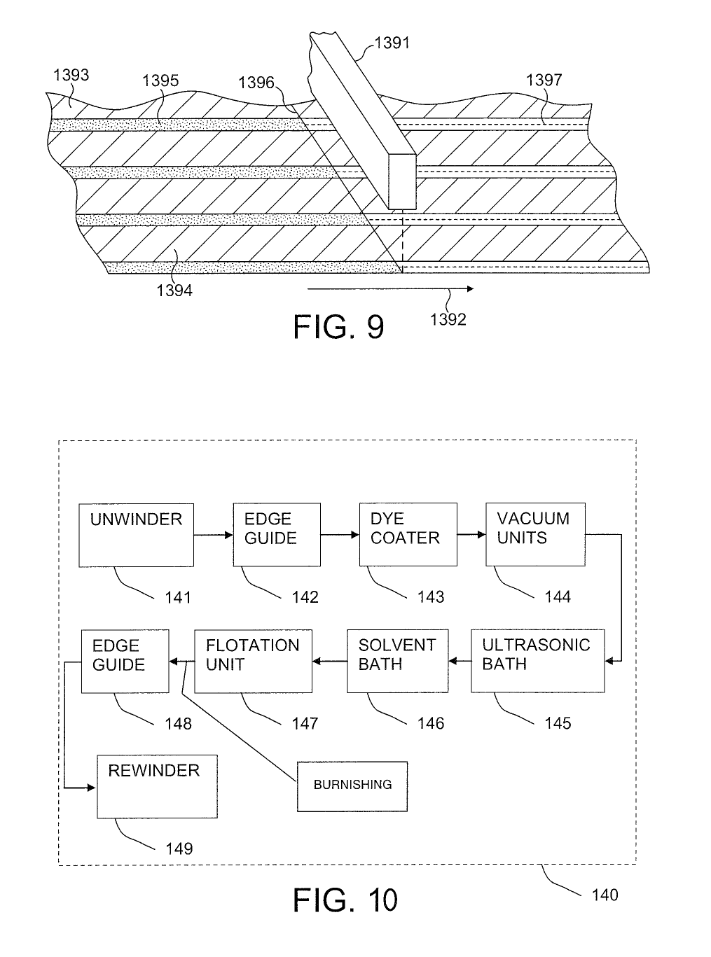

This arrangement is illustrated in FIG. 9. A laser 1391 is mounted above the path, indicated by arrow 1392, of the coated titanium web 1393. The web comprises tracks 1394 which have been coated with titanium dioxide and intervening tracks 1395 containing the embossed dimples which have undesirably been coated with a layer of titanium dioxide during the sintering process. The laser 1391 directs a beam of radiation along a scan line 1396, but such that only the intervening tracks 1395 containing the embossed dimples are irradiated. This is achieved either by scanning the laser beam across the entire width of the web, using either a scanning head or a beam-splitter, and modulating the intensity accordingly, or by directing the laser beam only at the intervening tracks 1395, such as by a fiber-optic arrangement. In either case, the power and frequency of the laser beam are selected and/or controlled such that the radiation is able to ablate the oxide layer from the surface of the titanium web 1393, and the resulting cleaned intervening tracks 1397 can be seen downstream of the laser beam in FIG. 9. In one embodiment, laser ablation is performed before a suitable dye is applied. In another embodiment, laser ablation can be performed at a plurality of different stages in the manufacturing process.

In an alternative arrangement, the entire surface of the titanium foil is coated with titanium dioxide paste using a simple extrusion head and then dried using the same three stages as described above. The tracks are then defined by removal of the titanium dioxide from the regions between the tracks using a high-power laser. This arrangement has the advantage of not requiring an extrusion head with a complex structure. In one embodiment, the width of each track of titanium dioxide coating is about 9.0 mm, and the separation between each pair of adjacent tracks is about 3.5 mm. Additionally, this method produces edges of the stripes of titanium dioxide that are primarily rectangular.

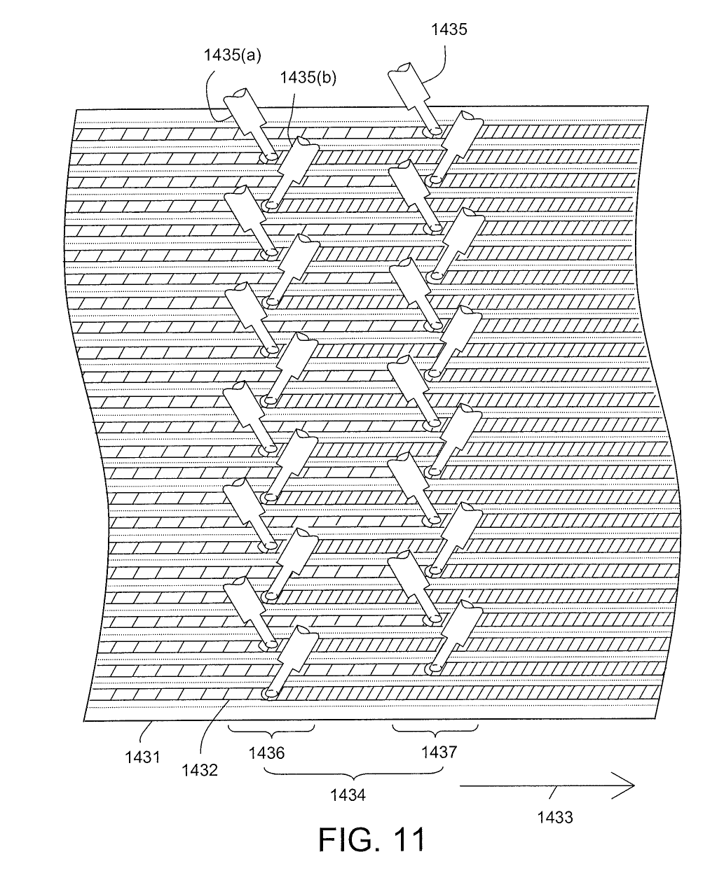

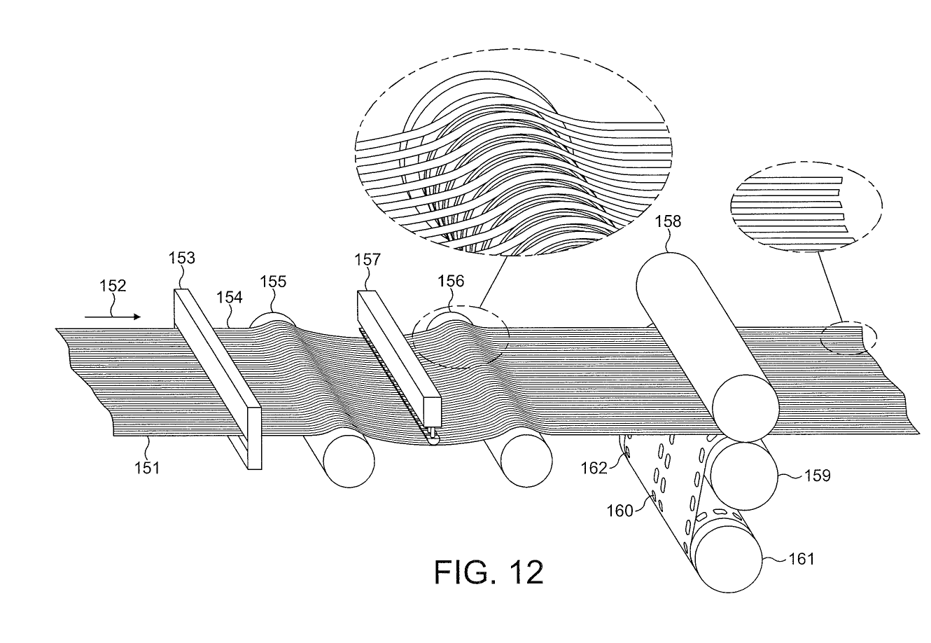

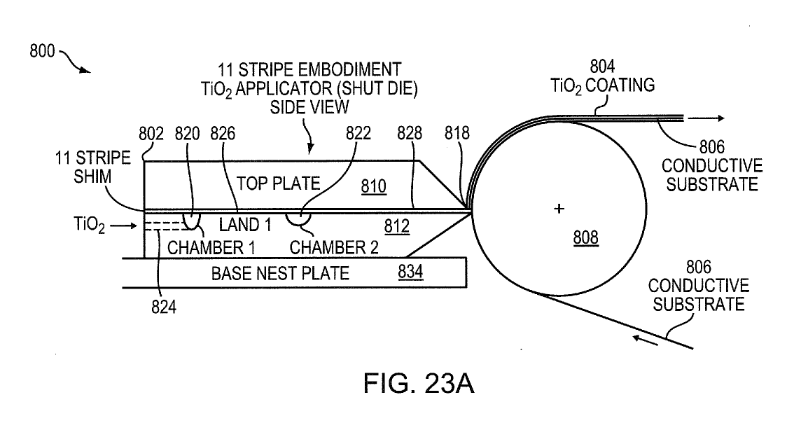

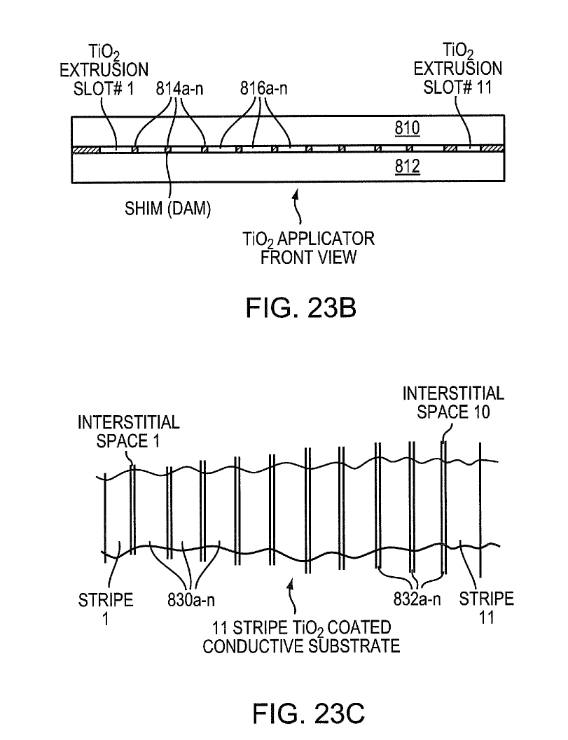

Referring to FIG. 10, an unwinder 141 supplies the TiO₂-coated Ti web via an edge guide 142 over infrared (IR) heaters, to remove residual water from the coating. The web is heated from the back side to prevent cracking of the titanium dioxide layer. The web then goes to a dye coating station 143 where a coating containing ruthenium dye is then applied to the TiO₂-coated Ti web, by a single or multiple dosing applicators, see FIG. 11. Other possible application methods include slot-die applicators, such as that described below with respect to FIGS. 23A and 23B, or inkjet. Another alternative is to imbibe dye via imbibing tanks. In one embodiment, the Ti web is then passed via two vacuum units 144, which dry the dye coating, to a first bath 145 which cleans the web ultrasonically and then to a second bath 146 containing a solvent cleaner. In another embodiment, the vacuum units 144, ultrasonic bath 145 and solvent bath 146 are eliminated. Instead, the Ti web is passed into an imbibe area where the dye is allowed to infiltrate or imbibe the TiO₂ coating, and then to an agitated rinse bath where excess dye is removed.

A flotation unit 147 then dries the web. A burnishing station can then be used to removed unwanted material as discussed above with respect to FIG. 2. The dried coated foil is then fed via an edge guide 148 to a rewinder 149.

It would be possible to apply the coating to the TiO₂-coated Ti web using an extrusion head which is identical to that used to apply the TiO₂ paste to the Ti web, in which case the dye-coating station 143 would be substantially identical to the TiO₂ application station (or applicator) 133. The rate at which the dye is applied is controlled by any precision application metering technique.

The TiO₂ and dye coated sheet is conveyed through a series of solvent baths to remove dye not bound to TiO₂. The coated web is then burnished to remove unwanted oxides in specified areas.

The web is guided through the coating processes at a tension that is governed by the stiffness of the web and its thickness. In one embodiment the web is held at a tension per unit width of the web of about 346 Nm⁻¹. This is found to be adequate to control the movement of the web, yet not sufficient to cause the coating to crack. In typical applications, in which the width of the web is about 0.306 m, the actual tension applied is about 106 N.

It will be appreciated that the laser cleaning process described above with reference to FIG. 9 could be applied in multiple singular locations in the process before or after the web has passed through the dye coating station.

The next stages in the fabrication of the primary electrode array are illustrated in FIG. 12. The coated titanium web 151 is transported along a direction indicated by arrow 152 to a cutting head 153 which comprises a linear array of multiple rotary cutter blades arranged to cut the coated titanium web 151 into multiple strips 154, which in one embodiment, each having a width of about 12.25 mm, which will form the primary electrodes in the resulting photovoltaic cell array. However, before the cutting process starts, an array of longitudinal slots are cut across the width of the coated titanium foil 151 at the desired multiple lateral positions using a punch tool or automated cutter. This has been found to overcome the tendency for the flexible cutting blades to drift away from their desired lateral position. The edges of each of the resulting multiple strips 154 includes uncoated titanium, and each strip 154 has a respective line of embossed dimples running adjacent one of its two edges. In other embodiments the pre-punching prior to slitting is unnecessary.

The strips 154 are then supplied to first and second cylindrical guide rollers 155, 156 each of which is profiled so as to define multiple spaced parallel channels to guide the respective multiple strips 154 of the coated titanium web. Although the spacing between each adjacent pair of channels is only about 0.25 mm, it will be appreciated that this nevertheless gives rise to a difference in path length between the outermost strips and the innermost strips. To overcome this problem, a dynamic tensioning device 157 is provided between the first and second guide rollers 155, 156, and this serves the dual function of (a) defining a greater path length between the cutting head 153 and the second cylindrical guide roller 156 for those strips 154 which have been cut from the center of the coated titanium foil than for those strips which have been cut from the edges; and (b) applying substantially the same tension to each of the strips 154.

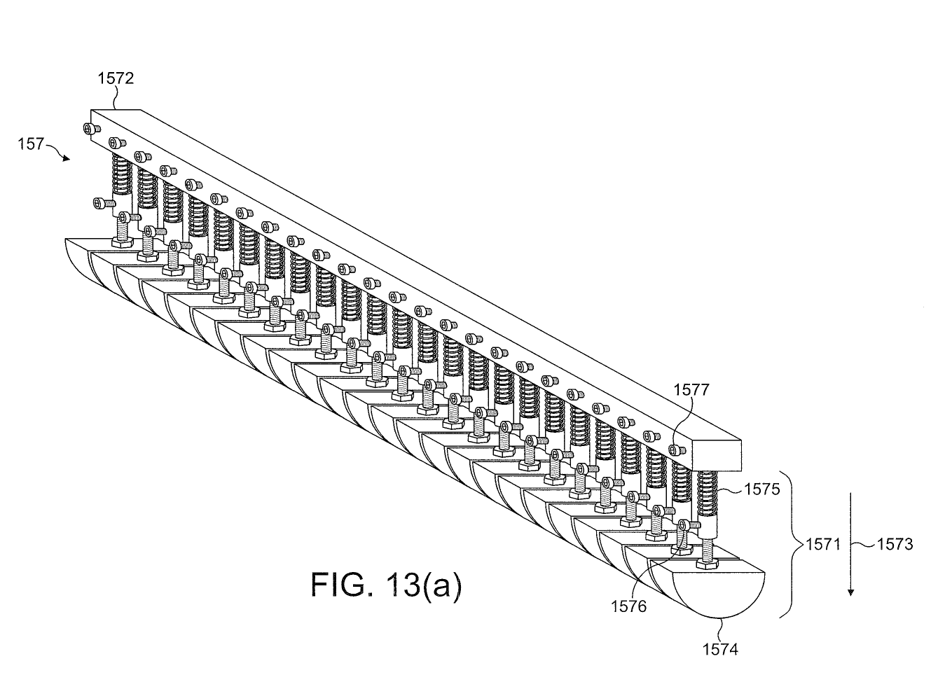

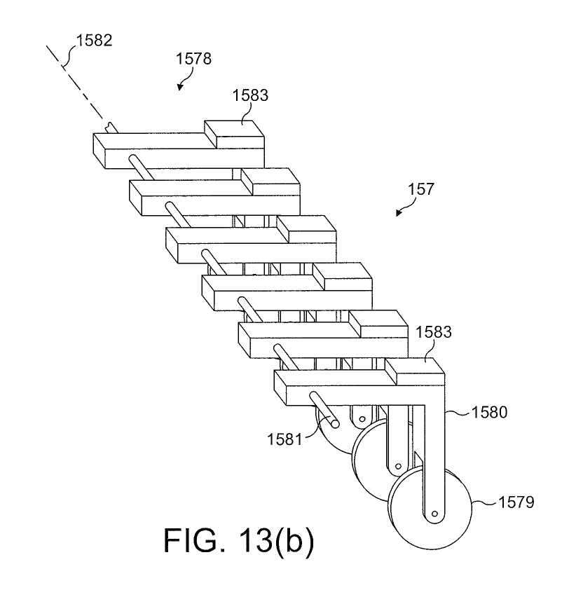

The dynamic tensioning device 157 can take one of two different forms. In the first arrangement, illustrated in FIG. 13(a), the device 157 comprises a linear array of multiple independently controlled dancers 1571 supported below a frame 1572 and which are biased vertically downwards, i.e. in the direction indicted by the arrow 1573. Each dancer 1571 comprises a semi-circularly cylindrical actuator 1574 made from polytetrafluoroethylene (PTFE), with the circular part facing downwards and therefore in a position to contact the upper surface of the strips 154 of coated titanium web. Each dancer 1571 further comprises a compression spring 1575, the biasing force of which is adjusted by means of first screw 1576. Furthermore, the stroke length of the dancer, i.e. the maximum vertical distance over which it can move, is adjusted by means of a second screw 1577, which attaches the dancer 1571 to the frame 1572. The height of the frame 1572 is controlled pneumatically, which enables the overall tension applied to the 24 strips 154 of coated titanium web to be adjusted.

In the second arrangement, illustrated in FIG. 13(b), each of the 24 dancers 1571, described above with reference to FIG. 13(a), has been replaced with a respective tensioning element 1578 comprising a plastic wheel 1579 supported for rotation below an arm 1580 which is itself arranged to pivot about a shaft 1581 which defines a pivot axis 1582. Tension is applied by means of a weight 1583 attached to the upper surface of the arm 1580 at its greatest perpendicular distance from the pivot axis 1582, so as to maximise the applied moment. With this arrangement, since the wheel 1579 is caused to rotate by the movement of one of the strips 154 of coated titanium web, there is minimal friction between the surface of the wheel 1579 and the strip 154, thereby reducing the likelihood of both (a) damage to the strip 154 and (b) wear to the surface of the wheel 1579. Furthermore, since the arm 1580 is free to pivot about a horizontal axis, there is unlikely to be any damage to the dynamic tensioning device 157 caused by the tendency of the moving strip 154 to apply a force to the device 157 along the direction of travel of the strip 154, since such force would merely cause the device 157 to pivot about the axis 1582.

Referring back to FIG. 12, the cut coated titanium strips 154 are then transported, with the embossed dimples facing upwards, to a nip defined between two rollers 158, 159. A web 160 of polyethylene terephthalate (PET) from a roll 161 is also supplied to the nip at a position below the cut coated titanium strips 154, which will form the substrate of the primary electrode array. In one embodiment the PET web 160 is pre-formed with four rows of rounded elongate holes 162, about 5 mm in width and about 20 mm in length, and which are positioned along the width of the web such that they are in register with the 1^{st}, 12^{th}, 13^{th} and 24^{th} strips 154 of the coated titanium foil, so as to expose portions of these strips 154 in the final photovoltaic cell array which will permit a direct electrical connection to be established directly to the exposed titanium foil at each side edge of the finished photovoltaic cell array. The PET web 160 carries a layer of thermal adhesive, so that the strips 154 are pressed against the thermal adhesive by the rollers 158, 159. The rollers 158, 159 are heated so as to activate the thermal adhesive to adhere the strips 154 to the PET web 160. The strips 154 are thereby attached to the underlying PET carrier web 160, with the spacing between adjacent pairs of strips 154 maintained at about 0.25 mm which will form an insulating track in the primary electrode array which separates the respective primary electrodes within the array.

In an alternative arrangement, the channelled rollers described above with reference to FIG. 12 are replaced with a roller which is formed with a convex surface when viewed along the direction perpendicular to the roller axis. In this arrangement, the surface profile of the roller causes the strips 154 of the coated titanium web to become spaced laterally from each other and also prevents differential tensions arising in the strips 154. The cut strips 154 are then fed to a guide roller which is formed with a series of vertical ridges of about 2 mm height which serve to retain the cut strips 154 in a desired lateral position before being deposited on the underlying PET substrate 160.

The resulting structure of the primary electrode array is illustrated in the lower half of FIG. 20(a), to be described in greater detail below, in which each adjacent pair of strips of the coated titanium layer 501 is separated by an insulating gap 503 which is adjacent the lines of embossed dimples 502. As can be seen from FIG. 20(b), which illustrates both the primary electrode array and the counter-electrode array assembled to form the photovoltaic cell array, the dimples serve the dual function of initiating the separation between the primary electrodes and counter-electrodes and establishing an electrical connection between the electrodes in the assembled photovoltaic cell array.

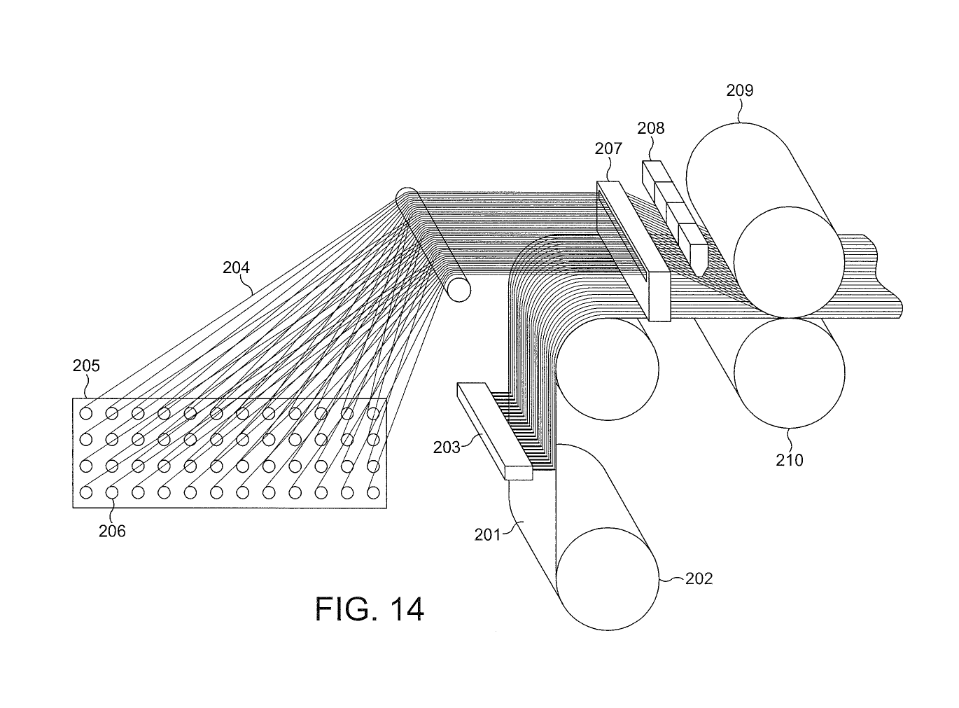

The process for forming the counter-electrode array is illustrated in FIG. 14. A web 201 of polyethylene naphthalate (PEN) which is coated with a conductive layer of, for example, indium tin oxide (ITO) is transported from a supply roll 202 and guided past a row of 24 scoring pins 203 which are made of tungsten and formed with tungsten carbide tips, and which are heated to a temperature that reduces softening/melting point of the PEN. These pins 203 serve to score the surface of the coated PEN layer, so as to remove the ITO coating and thereby expose the underlying PEN substrate, along multiple parallel lines which are spaced apart by a distance of 12.50 mm, which is the width of each cell of the final photovoltaic cell array, such that there is a single line in the same position within each cell. These lines serve as insulating tracks, as indicated by the reference numeral 510 in FIGS. 20(a) and 20(b), to be described in greater detail below.

Insulating fibers 204 are then deposited on the scored coated PEN substrate 201. The fibers 204 are supplied from a 4×12 array 205 of 48 bobbins 206, on each of which is wound a supply of insulating fiber 204. Although specific details relating the size of the array and the number of bobbins are provided, for various embodiments different sizes and numbers can be used without limitation as appropriate for a given embodiment. Each fiber 204 is preferably made from an aramid material, for example a para-aramid synthetic material, marketed under the brand name Kevlar®, and coated with a resinous hot-melt thermoplastic polymer adhesive. The para-aramid core of each of the 48 fibers 204 constitutes a number of separate threads and have a diameter of about 0.3 mm to about 0.10 mm. Although 48 fibers is one example, different numbers of fibers can be used in various embodiments. The resin coating of 24 of the fibers 204 has a thickness of 100 μm, whereas the thickness of the coating of the remaining 24 fibers 204 is about 50 μm, so that the resulting outer diameters of the two types of coated fiber 204 are about 150 μm and about 250 μm respectively.

The scored web 201 is supplied, together with the 48 insulating fibers 204, to a fiber alignment head 207 in which each of the 48 fibers 204 is aligned laterally between a respective pair of guide pins (not shown) at the appropriate lateral position for deposition on the underlying coated PEN substrate. The fibers 204 are deposited in pairs, the separation between the fibers 204 in each pair being substantially less than the spacing between adjacent pairs. Typically, the separation between the fibers 204 in each pair is approximately 1 mm, while the spacing between adjacent pairs is approximately 12.5 mm. The 24 coated fibers 204 having the smaller outer diameter are deposited directly over the 24 scored lines in the PEN substrate, and the 24 coated fibers 204 with the larger outer diameter are formed in parallel lines running closely adjacent the smaller fibers 204.

The aligned fibers 204 are then caused to pass below a row of four hot air knives 208 which direct air heated to between 80 and 150° C. on to the fibers 204. The heated fibers 204 are then supplied to a nip defined between two heated rollers 209, 210 which melt the adhesive resin coating and thereby bind the fibers 204 to the coated PEN substrate. The function of the hot air knives 208 is to pre-heat the fibers 204, so that the adhesive resin can more readily be melted by the heated rollers 209, 210.

In an alternative embodiment, air nozzles are used instead of the air knives.

The fibers will form insulating spacers between the primary electrodes and counter-electrode arrays in the final photovoltaic cell array, as can be seen more clearly from FIGS. 20(a) and 20(b), to be described in greater detail below, in which the smaller diameter fiber 508 is shown in the position aligned with the scored insulating line 510 on the PEN insulating substrate 506, and the larger diameter fiber 509 runs parallel thereto. In the photovoltaic cell array, the two fibers within each pair run along either side of a respective line of the embossed dimples formed on the primary electrodes.

In another embodiment, grooved lamination rollers with grooves aligned at the correct pitch of placement on the counter-electrode are heated to the softening point of the adhesive and laminated in situ to the pre-heated PEN substrate there by guaranteeing exact fiber placement on either the counter-electrode or the primary electrode. The coated PEN substrate with the attached fibers is then cut to the desired width by means of a selected one or more of a row of ten evenly spaced hydraulically operated cutting heads (not shown). The desired width represents the number of photovoltaic cells required in the final array. The finished counter-electrode array is then wound on to a roll at a rewinder station or maybe fabricated in situ with the primary electrode and both counter electrode/primary electrode are joined with electrolyte application in a single operation/pass.

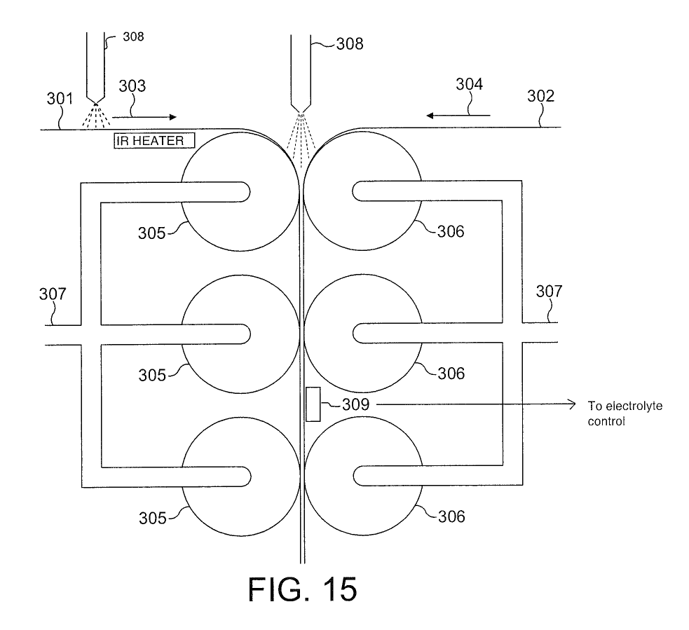

At this stage, the manufacture of the separate primary electrode and counter-electrode arrays is complete. The two electrode arrays are now joined together, and the resulting channels defined between the two electrode arrays are filled with electrolyte, as will now be described with reference to FIG. 15.

A first level of pressure is associated with the top or first roller pair shown in FIG. 15. In turn, a second level of pressure is associated with the second or middle roller pair shown in FIG. 15. Finally, a third level of pressure is associated with the bottom or third roller pair shown in FIG. 15. The third level of pressure generated by the first pair is greater than the second level of pressure generated by the second pair which is in turn greater than the level of pressure generated by the first pair. This increase in roller generated pressure is sequentially adjusted to improve the distribution of electrolyte and proper alignment of the adhesive portions. In one embodiment, the first and second roller pairs include ribs or other patterned surfaces while the third or bottom pair of rollers are flat. The use of the flat rollers facilitates squeezing the electrolyte or otherwise aligning the cells containing the electrolyte. This use of different roller configurations facilitates lamination of a primary and counter electrode coupled with in-situ filling of electrolyte. As a result, such a system allows for progressive activation and spread of adhesive and electrolyte distribution as a result of the sequential multiple variable pressurised laminating roller pair array depicted in the figure.

In one embodiment, after the fluid is squeezed using the last flat roller pair, the pressure from the rollers forces some of the liquid electrolyte to rise above the nip or junction of bottom roller pair (typically a flat roller pair). This column of squeezed electrolyte can be scanned, tracked, measured, or otherwise evaluated using an electrical, mechanical, or optical device. In one embodiment, a suitable meniscus detector 309, such as charge coupled device array, can be used to scan the meniscus to detect the height of the meniscus and the stability of the meniscus height. Variation in the meniscus height, such as time varying meniscus height, that increases or decreases can be used as control variable for a feedback loop that increases or decreases the flow rate of the electrolyte dispenses using the first, second, or both nozzle arrays 308.

If the meniscus level rises, this means too much fluid is entering the cells. Thus, the detector 309 can scan up and down while allowing the meniscus to rise or fall by a set acceptable amount, which corresponds to the cell being filled appropriately for the desired volume for the cell. If too much fluid enters, the sensor triggers a slow down in fluid flow rate via the applicators 308. If the meniscus height is sensed as dropping, then the rate the meniscus is falling can be used to increase the flow rate of the electrolyte to compensate for the under filling of the cells.

As shown in FIG. 15, in order to join together the two electrode arrays, the primary electrode array 301 and the counter-electrode array 302 are transported in the respective directions indicated by arrows 303, 304 to the top of a vertical path defined between three pairs of opposing rollers 305, 306 (top/first, middle/second, bottom/third, as discussed above) which are heated by feeding a supply of heated oil into a channel 307 within each of the rollers 305, 306. One of each pair of rollers 305, 306 has a resilient rubberised surface. At the same time a supply of liquid electrolyte is injected from a row of nozzles 308 into the channels defined between the respective pairs of fibers of the counter-electrode which are now between the primary electrode array 301 and the counter-electrode array 302. In one example, 22 nozzles are provided. It would be possible to supply all of the 22 nozzles with the electrolyte using a single peristaltic pump. However, such an arrangement does not permit the flow of electrolyte from each nozzle 308 into its respective channel to be controlled independently. Another embodiment the nozzles 308 are therefore formed from one or more rows of solenoid-controlled dosing valves similar to those used in the dye-coating station described above with reference to FIG. 11. The level of the electrolyte (meniscus height) within the multiple channels is sensed 309 located downstream of the dosing nozzles 308, and the output signal from the sensors 309 is used to control the rate of flow of the electrolyte into the channels to keep the meniscus level constant.

Similarly, as shown in FIG. 15, in another embodiment, multiple electrolyte application or dosing arrays 308 may be arranged to apply electrolyte in sequential applications prior to electrolyte application at laminator nip #1 305/306 (junction of top roller pair). For example, as shown at the top portion of the figure, a first and a second nozzle array 308 can be used to apply electrolyte sequentially at different locations. Multiple electrolyte applications may have the added benefit of partially filling the TiO₂ mesoporic coating (sponge) and therefore giving a more efficient filling of the mesoporic sponge due to an extended time for the electrolyte to permeate the TiO₂ layer before applying the final filling dose of electrolyte applied at nip #1 305/306.

As shown in FIG. 15, a first and second electrolyte applicator or nozzle array 308 is shown. The first electrolyte applicator is positioned before the nip while the web is flat before the nip is encountered between the first roller pair or top roller pair. Further, the second electrolyte applicator can be positioned above the nip along the line formed by the junction of the three roller pairs as shown. In another embodiment, the electrolyte may be separated into two parts, one with a larger amount of solvent, and the other with a larger amount of electrolyte. One possible combination would be to have the first fluid be a mixture of about 67% solvent and about 33% electrolyte, and the second fluid be a mixture of about 33% solvent and about 67% electrolyte. This technique allows for greater permeation of the electrolyte into the mesoporic TiO₂ coating. Heating the primary electrode array between application points will also increase the rate of electrolyte permeation into the TiO2 mesoporic coating by reducing viscosity and surface tension. An infrared heating element (shown in the top portion of the figure) can be used to achieve these beneficial electrolyte changes.

As shown, the surfaces of the top and middle pair of rollers 305, 306 are formed with opposing ridges which are positioned relative to the electrode webs 301, 302 such that the pairs of coated fibers are compressed between the opposing ridges thereby to cause the resin adhesive coating on the fibers to conform to the shape of the primary electrode structure, as can be seen more clearly from FIGS. 20(a) and 20(b). As discussed above, the bottom roller pair 305, 306 in FIG. 15 uses flat rollers in a preferred embodiment.

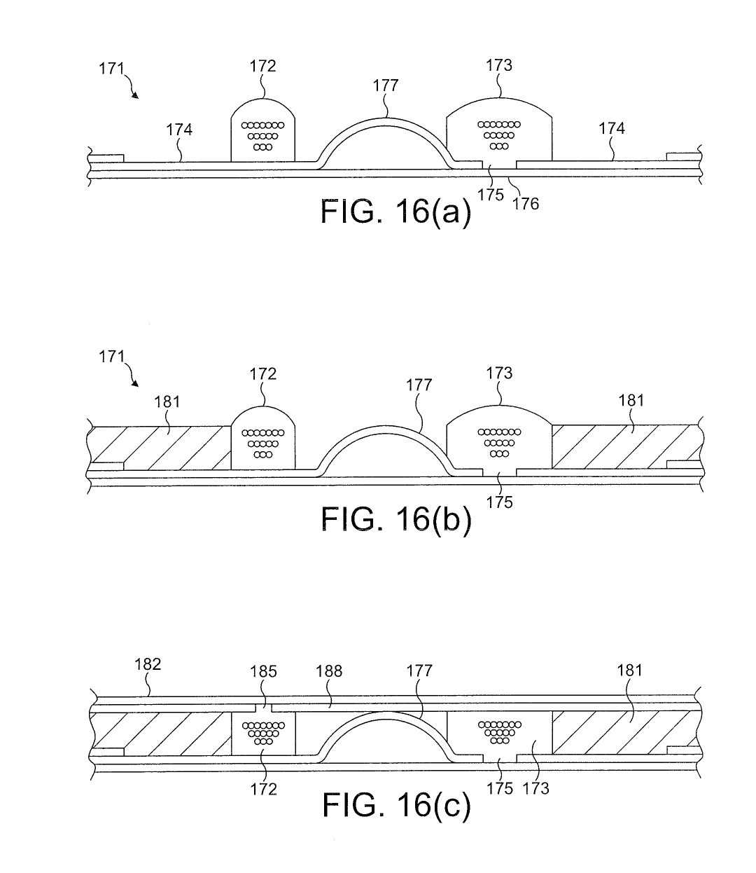

In an alternative arrangement, the multiple coated insulating fibers are deposited on the primary electrode array, instead of the counter-electrode array. In this arrangement, the primary electrode array is supplied, together with the multiple fibers, to a nip defined between two heated rollers which melt the adhesive resin coating and bind the fibers to the titanium web at their respective positions along pairs of parallel lines running each side of the lines of embossed dimples. As with the arrangement described above in which the fibers are deposited on the counter-electrode array, a linear array of hot air knives is arranged to direct hot air on to the fibers immediately upstream of the nip and serves to pre-heat the fibers, so that the adhesive resin can more readily be melted by the heated rollers. The resulting structure of the primary electrode array 171 is illustrated in FIG. 16(a), in which it can be seen that the coating of the insulating fibers 172, 173 has partly melted, so that the thinner of the two fibers 172 in each pair of fibers is firmly adhered to the underlying titanium web strip 174 and the thicker of the two fibers 173 runs along the insulating track 175 formed in the primary electrode 171 between the ends of the titanium strips 174, and is firmly adhered to both the end regions of the underlying adjacent titanium strips 174 and also to the PET substrate 176. Each adjacent pair of fibers 172, 173 is deposited in lines running either side of a respective line of embossed dimples 177. Although two fibers 172 and 173 are shown, in one embodiment a multiplicity of fibers can be used. By using additional insulating fibers (more than two) bond strength and improved manufacturing robustness can be achieved.

In another embodiment the insulating fibers are deposited on the counter-electrode. In a further embodiment a third fiber is attached to the counter-electrode at the center line of the scored groove.

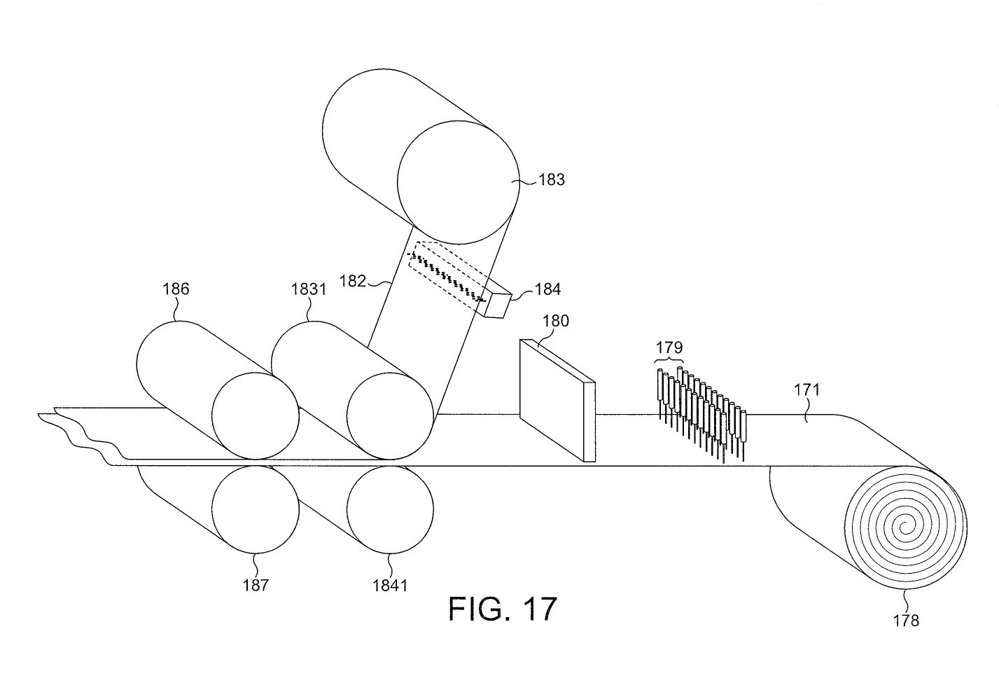

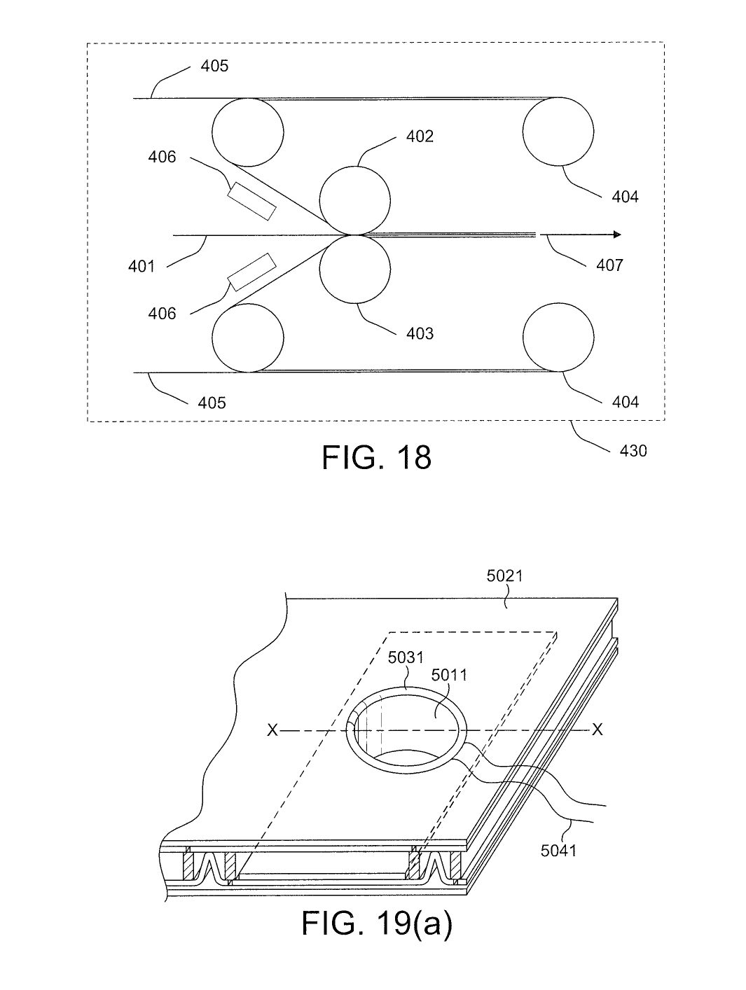

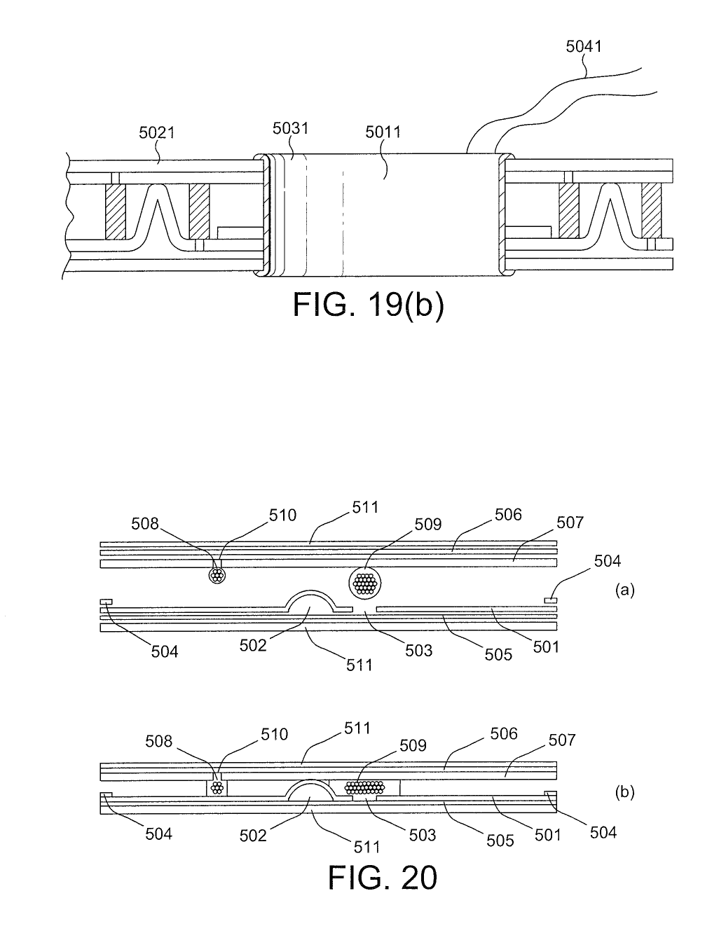

With this arrangement, the electrolyte is deposited into the channels formed between alternate pairs of coated insulating fibers 172, 173 when the primary electrode is oriented horizontally, in a process illustrated in FIG. 17. In this arrangement, the primary electrode array 171 is transported from a supply roll 178 to an electrolyte filling station 179 at which the electrolyte is deposited on to the primary electrode array 171 when in a horizontal orientation. The electrolyte is supplied from multiple solenoid-controlled dosing valves arranged in one or more linear arrays, similar to those described above with reference to FIG. 11. Since the primary electrode array 171 is horizontal, the electrolyte will, under gravity, fill the channels between alternate pairs of coated fibers. During the filling process, the level of the electrolyte within the 22 channels is sensed using a row of multiple sensors 180, located downstream of the electrolyte filling station 179 in the direction of transport of the primary electrode array 171. The specified control of the rate of electrolyte deposition is achieved by adjusting the rate of flow of electrolyte of nominal deposition and the structure of the primary electrode array 171 immediately after filling with the electrolyte is illustrated in FIG. 16(b), where it can be seen that the electrolyte 181 fills the channels defined between alternative pairs of the insulating fibers 172, 173.

In a yet further arrangement, the thicker 24 of the 48 fibers are deposited directly on to the insulating tracks formed in the primary electrode array, and the thinner 24 of the 48 fibers are deposited directly on to the insulating tracks formed in the counter-electrode array. The method of deposition of the respective fibers is as described above. With this arrangement, the ease of alignment of all of the fibers is enhanced.

In a further embodiment, instead of using Kevlar fibers coated with hot-melt adhesive as insulating spacers, only the hot-melt adhesive is used, in which case, a supply of the hot-melt adhesive is pre-heated and then extruded directly on to the surface of either or both (a) the primary electrode array in parallel lines running adjacent the lines of embossed dimples or (b) the counter-electrode array, again in parallel lines at the corresponding positions.

In a modification of this further embodiment, the hot-melt adhesive is supplied with 50 μm-diameter spherical beads of silicon dioxide glass which, when deposited on either the primary electrode array or the counter-electrode array, serve, in conjunction with the lines of embossed dimples, to define the spacing between the two electrode arrays in the assembled photovoltaic cell array and provide insulation (spacing) to minimise risk of short circuiting between counter-electrode and primary electrode due to burred Ti foil edges on non-embossed foil stripe touching the counter-electrode TCO coatings.

In each of the above arrangements for forming the assembly of the two electrode arrays, the required length of the electrode assembly is then cut manually using a guillotine.

In order to prevent the electrolyte from escaping from the ends of the channels between the two electrode webs, both the leading and trailing edges of the cut length are sealed by placing the assembly on an edge-sealing table and applying a hot-melt adhesive, which is heated to 180° C., to each of the edges in turn to the PV architecture herein described the preferred embodiment after end sealing moves through continuing process where bypass diodes are attached in parallel across the active cells to prevent reverse bias of the cells initiating device degradation.

To the above array power leads, are attached and the module array is encapsulated with a stack of materials on both the front and back to minimise the effects of the environment and potential physical damage due to user deployment.

The counter-electrode array is formed from a continuous insulating substrate 506 made from PEN which is coated with a conductive layer 507 of ITO and having relatively thinly coated fibers 508 and relatively thickly coated fibers 509, the thinner fibers 508 being aligned with insulating tracks 510 formed in the conductive layer 507 of ITO.

FIG. 20(b) is a cross-sectional view of a portion of two adjacent cells of the photovoltaic array after assembly and lamination, in which the outer surfaces of the two insulating substrates 505, 506 are each coated with a respective laminate layer 511.

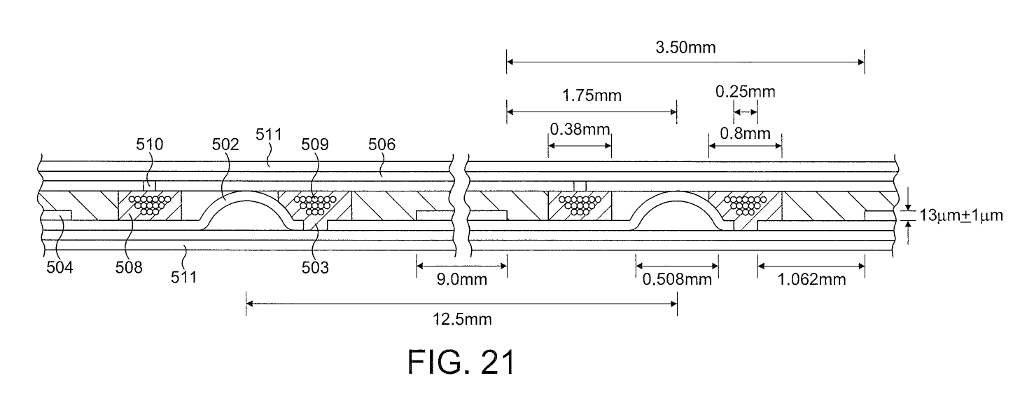

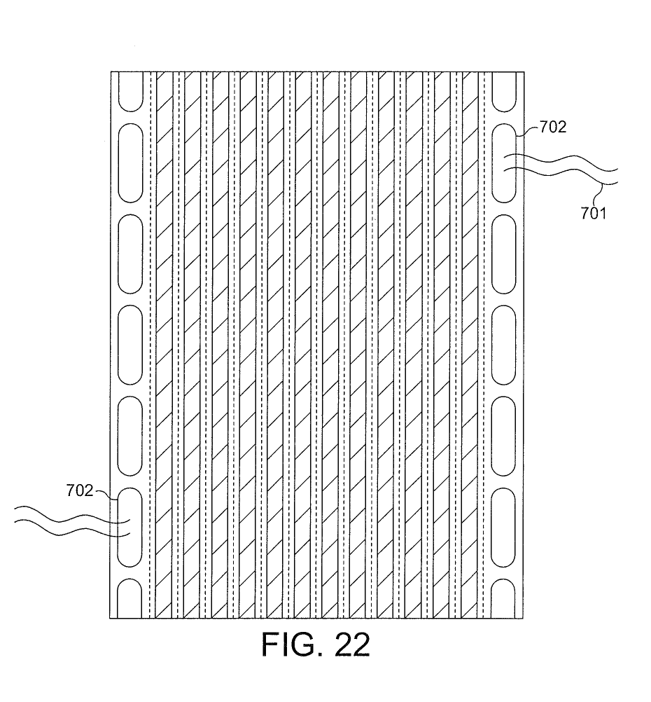

FIG. 21 illustrates the dimensions of the components of the finished photovoltaic cell array in accordance with a preferred embodiment of the present invention. The representation in the drawing is not to scale, and the vertical dimension is exaggerated for the sake of clarity.

FIG. 22 illustrates the overall appearance of a finished array of 12 photovoltaic cells. In this case, external electrical connections 701 are made to the titanium web through two of the elongate apertures 702 formed along the side edges of the PET substrate of the primary electrode array. It will be appreciated that the finished array may comprise a different number of photovoltaic cells. In a preferred embodiment, for example, the finished array comprises 11 photovoltaic cells.

FIGS. 23a-c show a TiO₂ colloid applicator system 800 in accordance with an illustrative embodiment of the invention. Referring to FIG. 23a, which shows a side profile view of the applicator system, applicator system 800 includes an applicator head (i.e., slot die) 802 that deposits a TiO₂ coating 804 on a conductive substrate 806. Conductive substrate 806 is continuously fed across applicator head 802 by roller 808. Applicator head 802 includes a top plate 810 and a bottom plate 812. Applicator head 802 can be supported by a base nest plate 834 which communicates directly or indirectly with applicator head placement controls (not shown). In a preferred embodiment, top plate 810 and bottom plate 812 have a trapezoidal profile such that a tapered applicator port 818 is formed. In one embodiment, the port connects or terminates in a tapered continuous lip. The applicator lip is formed such it is continuous. In one embodiment, the lip is substantially free of periodic or random notches.

Referring to FIG. 23b, which shows a front view of applicator head 802, top plate 810 and bottom plate 812 are separated by a plurality of evenly spaced transverse shims (i.e., interstitial dams) 814a-n. When top plate 810 and bottom plate 812 are mated, the plurality of shims 814a-n create a plurality of extrusion slots 816a-n between top plate 810 and bottom plate 812. The size of the extrusion slots 816a-n is dependent, in part, upon the width and height of the shims. Thus, the volume of TiO₂ colloid flowing through the plurality of extrusion slots 816a-n can be controlled, in part, by altering shim dimensions.

Referring to FIG. 23a, bottom plate 812 can include a first channel 820 and a second channel 822 which run substantially parallel to the long axis of the bottom plate 812. In some embodiments, more than two channels are used. A first land 826 separates first channel 820 and second channel 822, and a second land 828 separates second channel 822 from extrusion port 818. TiO₂ colloid is supplied to the first channel 820 via one or more supply channels 824 which supply TiO₂ colloid to the first channel 820 and/or the second channel 822 from the rear of the applicator. First channel 820, second channel 822, and supply channel 824 can be formed in bottom plate 812 by, for example, molding or milling processes. In some embodiments, first channel 820 is in fluid communication with the plurality extrusion slots 816a-n such that TiO₂ colloid flows from first channel 820 into the plurality of extrusion slots 816a-n. First channel 820 and second channel 822 are useful to control TiO₂ colloid flow and pressure within the extrusion slots 816a-n. In one embodiment, the first channel 820 provides a coarse level of correction and the second channel 822 provides a fine correction. The relationship of the length of the lands and the height of the channels are determined based on the rheology of the fluid being deposited to form a portion of a DSSC as shown. Since the colloids used are typically non-Newtonian in nature, the use of the lands to provide pressure drops in conjunction with the channels help properly regulate flow properties to create working DSSCs.

Referring to FIG. 23c, which shows a top view of a TiO₂ coated conductive substrate, applicator head 802 deposits a plurality of TiO₂ stripes 830a-n on conductive substrate 806 as conductive substrate 806 is fed across extrusion port 818 of applicator head 802. As will be appreciated, applicator head 802 can be configured to deposit any number of TiO₂ stripes on conductive substrate 806. The plurality of stripes 830a-n are separated by a plurality of interstitial spaces 832a-n. The width of the interstitial spaces 832a-n is dependant, in part, upon the dimensions of the shims 814a-n. As shown, the number of cells, width of cells, length of cells, etc. can be adjusted by changing the geometry of the shim or shims used. In one embodiment, each stripe is connected in series across the substrate when the cells are formed

In a preferred embodiment, the variation in the width, length, or other geometric, electrical, or performance characteristics of the TiO₂ stripes and the DSSCs which they form are less than about 5% (or about 3% in another embodiment). In some embodiments, the plurality of shims 814a-n are removed, thereby allowing for a continuous TiO₂ coating across conductive substrate 306. The mesoporic sponge needs to be substantially uniform in width and in thickness to align and prevent mismatch when forming the DSSCs. If there is a mismatch that results in greater than 5% deviations between each DSSC, then cell failure is likely to occur as a result of resistance and short circuit events.

Thus, in one embodiment, the performance characteristics of each DSSC are designed to be substantially the same such that a performance characteristic or other cell parameter varies by less than about 5%, about 3%, or about 1% when comparing different cells. Suitable performance characteristics can include, but are not limited to an alignment measure or distance, current, voltage, electrolyte volume, constituent layer thickness, and other dimensions associated with each layer present in a given DSSC embodiment.

### Examples and Additional Embodiments

It will be appreciated that the flexible arrays of photovoltaic cells manufactured in accordance with the above processes have wide-ranging applications. In addition, there are various innovative features and embodiments related to the disclosure and examples described herein.

In one embodiment, a two stage application of electrolyte is used. By using a plurality of electrolyte applicators, it is possible to improve electrolyte permeation in the relevant constituent layers of a given DSSC embodiment. When this is coupled with heating, such as infrared heating, enhanced electrolyte diffusion is achieved. The two stage application of electrolyte can be further enhanced in some embodiments by applying different mixes or ratio of the solvent and ionic components of the electrolyte to improve viscosity and other parameters. Typically, the different mixtures of electrolytes are chosen such that when they combine in a cell as part of a roll to roll process a predetermined electrolyte mixture results, such as that used when only a single electrolyte applicator (or array) is used.

In one embodiment, the embossing patterned used is selected to increase or substantially maximize cell to cell electrical interconnection. Thus, an elongate embossing pattern can be used, such as a diamond or other suitably shaped pattern that is greater in length relative to width. In one embodiment, the use of an elongate pattern can be used in the transverse direction rather than in the web direction. Alternatively, the elongate pattern can be used with an orientation along the web direction as opposed to the transverse direction in one embodiment. The emboss pattern forms the electrical interconnection. Accordingly, the shape of the emboss feature can be changed in height, width, and depth and other parameters. Variations in the shape of the emboss features can be used to improve the application of adhesive during DSSC manufacture.

In one preferred embodiment an emboss feature is selected that forms hinges as a result of the embossing features used and is thus suitable for use in a photovoltaic array that can be rolled and transported in tube shaped case. Such a rollable photovoltaic array is suitable for use as window shade, awning, or any other rolled sheet application. Typically, in such a rollable embodiment, the underlying emboss pattern is oblong or elongated and rotated transverse to the machine direction. The use of a round or oblong emboss pattern having a greater interval between emboss features would also affect a less stiff PV in the machine direction and facilitate a hinge-like structure amenable to rolling.

In one embodiment, the roll to roll manufacturing process described herein results in an array of DSSCs can be cut along any length along or across the web direction without an electrical short occurring.

A slot die applicator can be used as discussed relative to FIGS. 23a-23c. In one embodiment, the slot die applicator design affects uniform TiO₂ coating uniformity with TiO₂ colloid rheology design. Thus, the rheology of the colloid is used to select a first height for the channel, a first distance for the first land, a second height for the second channel, and second distance for the second land. In addition, the shim geometry may be adjusted based on the rheology of the colloid being used. This results in uniform stripes being deposited which in turn allows for proper cell formation and alignment.

In one embodiment, a significant reduction of TiO₂ sintering and dye imbibe cycle time is achieved relative to typical DSSC sintering and dye imbibe times. In part, the sintering time is achieved using a sintering profile wherein the TiO₂ is sintered for about 5 seconds at 650 degrees Celsius. In one embodiment, the sintering is performed using an infrared heating element and by controlling the sintering profile as part of the roll to roll manufacturing process. The sintering is a dynamic process in that it is performed while the relevant substrate is transported through the manufacturing process.

In one embodiment, the entire manufacturing process is roll to roll. Since a roll to roll process is used with modular stations and elements there is flexibility to change cell size and other DSSC parameters, i.e. number, width, length of cells without substantial retooling.

Each patent and non-patent reference cited in the application is hereby incorporated by reference herein.

The various aspects, embodiments, and features of the invention described herein are to be considered illustrative in all aspects and are not intended to limit the invention, the scope of which is defined solely by the claims. In addition, other embodiments are possible and modifications can be made without departing from the spirit and scope of the claimed invention.

What is claimed is:

1. A method of forming a dye sensitized solar cell, the method comprising the steps of:
(a) applying an electrolyte mixture to a first electrode web in at least two doses;
(b) heating the electrolyte mixture to increase diffusion of the electrolyte mixture relative to the electrode web; and
(c) joining the first electrode web with a second electrode web to form a plurality of dye sensitized solar cells.

2. The method of claim 1 wherein the step of joining the first electrode web with the second electrode web is performed using a first textured roller pair, a second textured roller pair and a third flat roller pair, the pressure exerted on each electrode web by the second roller pair is greater than that exerted by the first roller pair.

3. The method of claim 1 wherein the electrolyte mixture comprises a first component and a second component.

4. The method of claim 1 wherein the first component comprises a greater amount of solvent relative to the second component.

5. The method of claim 1 wherein the first component comprises a greater amount of electrolyte relative to the second component.

6. The method of claim 5 wherein the first component comprises about 67% solvent and about 33% electrolyte.

7. The method of claim 6 wherein the second component comprises about 33% solvent and about 67% electrolyte.

8. A method of preparing a primary electrode array for use in a dye sensitized photovoltaic array, the method comprising the steps of:
(a) forming a component of the dye sensitized photovoltaic array by coating and drying a coating on a conductive substrate;
(b) heating the coating to sinter the titanium dioxide particles and to form an insulating layer of titanium oxides on the surface of the electrical conductor; and
(c) applying laser radiation to a first region of the surface of the electrical conductor, thereby to remove any coating formed thereon in step (b).

9-11. (canceled)

12. A method as claimed in claim 8, wherein step (a) comprises applying a coating to substantially the entire surface of the electrical conductor.

13. A method as claimed in claim 8, wherein step (c) comprises transporting the electrical conductor in a transport direction relative to a source of laser radiation and scanning the laser radiation across the first region in a direction transverse to the transport direction.

14. A method as claimed in claim 8, wherein step (c) comprises transporting the electrical conductor in a transport direction relative to a source of laser radiation and applying the laser radiation simultaneously to those parts of the first region which intersect a linear region extending transverse to the transport direction.

15. The apparatus of claim 108, wherein the electrical conductor is in the form of a web.

16. The apparatus of claim 108, wherein the electrical conductor comprises titanium or alternative conductors.

17. The apparatus of claim 108, wherein the coating comprises titanium dioxide.

18. A method of manufacturing a primary electrode for a flexible dye sensitized photovoltaic array comprising a method of preparing a primary electrode array as claimed in claim 8.

19. A method of manufacturing a dye sensitized flexible photovoltaic array comprising a method of preparing a primary electrode array as claimed in claim 8.

20. A method of manufacturing a dye sensitized photovoltaic cell array of the type comprising a primary electrode array and a counter-electrode array together defining a series-connected sequence of cells, each containing electrolyte which is insulated from direct electrical contact with the electrolyte of neighboring cells, the method comprising:
(a) depositing electrolyte into the cells; and
(b) sensing the level of electrolyte deposited.

21. A method as claimed in claim 20, wherein the level of electrolyte in each cell is sensed independently.

22. A method as claimed in claim 20, wherein the level of electrolyte in each cell is sensed using one or more optical colorimetric sensors.

23. A method as claimed in claim 20, wherein the level of electrolyte is sensed using one or more optical reflective sensors.

24. A method as claimed in claim 20, further comprising controlling the rate of deposition of the electrolyte using a feedback loop that uses the sensed level of electrolyte as an input.

25. A method as claimed in claim 20, wherein the electrolyte is deposited using a separate respective dispenser, such as solenoid-controlled dosing valves, for each cell.

26. (canceled)

27. A method as claimed in claim 20, wherein each cell in the said one electrode array is defined by a respective pair of insulating tracks.

28. A method as claimed in claim 27, wherein each insulating track additionally comprises a plurality of insulating and adhesive media, some of which are applied to the primary electrode and some of which are applied to the counter-electrode, the insulating media defining the spacing between the primary electrode and the counter-electrode.

29-47. (canceled)

48. A method as claimed in claim 28, wherein the counter-electrode web comprises a layer of electrically conductive material on an electrically insulating substrate and the step of processing the web comprises forming a plurality of insulating tracks thereon by removing regions of the electrically conductive layer, thereby to create the counter-electrode array.

49. A method as claimed in claim 48, wherein the insulating tracks are formed on the web by one or more etching tools.

50-76. (canceled)

77. A method of establishing an external electrical connection to a dye sensitized photovoltaic cell array which comprises an alternating sequence of primary electrodes and counter-electrodes connected in series, the method comprising:
(a) forming a first aperture which extends through the first primary electrode within the sequence; and
(b) attaching a first electrical connector to the said first primary electrode such that it extends laterally on both sides of the first aperture and thereby engages the dye sensitized photovoltaic cell array.

78. A method as claimed in claim 77, further comprising:
(c) forming a second aperture which extends through the last primary electrode within the sequence; and
(d) attaching a second electrical connector to the said last primary electrode such that it extends laterally on both sides of the second aperture and thereby engages the dye sensitized photovoltaic cell array.

79. A method as claimed in claim 77, wherein the electrical connector is in the form of an eyelet.

80. A method as claimed in claim 77, wherein the electrical connector is attached to the first primary electrode by crimping.

81. A method as claimed in claim 80, further comprising attaching a conductive lead to the connector by simultaneously crimping both the electrical lead and the eyelet to the aperture.

82. A method as claimed in claim 77, further comprising attaching a conductive lead to the connector by soldering.

83. A method of manufacturing a dye sensitized flexible photovoltaic cell array comprising a method of establishing an external electrical connection thereto as claimed in claim 77.

84. A dye sensitized photovoltaic cell array comprising:
(a) a plurality of dye sensitized photovoltaic cells and an alternating sequence of primary electrodes and counter-electrodes connected in series, the first primary electrode within the sequence being formed with a first aperture therethrough; and
(b) a first electrical connector attached to the first primary electrode and extending laterally on both sides of the first aperture thereby engaging the plurality of dye sensitized photovoltaic cells.

85. The dye sensitized photovoltaic cell array of claim 84, the last primary electrode within the sequence being formed with a second aperture therethrough, the combination further comprising:
(c) a second electrical connector attached to the last primary electrode and extending laterally on both sides of the second aperture thereby engaging the plurality of dye sensitized photovoltaic cells.

86. Apparatus for manufacturing a flexible array of dye sensitized photovoltaic cells, the apparatus comprising: means for applying a paste to the surface of a conductive foil and means for drying the paste on the surface, to thereby form a pattern for a flexible array of dye sensitized photovoltaic cells.

87. (canceled)

88. (canceled)

89. Apparatus as claimed in claim 86, wherein the drying means comprises an infrared oven.

90. Apparatus as claimed in claim 89, wherein the drying means further comprises a combined infrared oven and hot air blower.

91-107. (canceled)

108. A dye sensitized photovoltaic array comprising:
a first region comprising one or more tracks along a surface of an electrical conductor; and
a second region comprising regions adjacent the one or more tracks along the surface of the electrical conductor;
wherein a coating is applied to only the second region.

109. A method for improving contact to integral electrical contacts on a conductive substrate and for improving adhesive properties of a portion of tracks which separate individual cells from each other in a dye sensitive photovoltaic array, the method comprising the steps of:
providing integral electrical contacts having an insulating coating on a conductive substrate;
providing tracks, having an insulating coating, which separate individual cells from each other in a dye sensitive photovoltaic array; and
using a laser to remove the insulating coating from the integral electrical contacts and from a portion of the tracks.
